(19) United States
(12) Patent Application Publication
(10) Pub. No.: US 2023/0418156 A1
(43) Pub. Date: Dec. 28, 2023

(54) METHOD OF MANUFACTURING A SEMICONDUCTOR DEVICE AND SEMICONDUCTOR DEVICE MANUFACTURING TOOL

(71) Applicant: TAIWAN SEMICONDUCTOR MANUFACTURING COMPANY, LTD., Hsinchu (TW)

(72) Inventors: Hui-Chun LEE, Hsinchu (TW); Tung-Hung FENG, Hsinchu (TW); Peng-Ting LEE, Hsinchu City (TW)

(21) Appl. No.: 18/107,427

(22) Filed: Feb. 8, 2023

Related U.S. Application Data
(60) Provisional application No. 63/356,423, filed on Jun. 28, 2022.

(51) Int. Cl. G03F 7/00; G03F 7/16; G03F 7/20; G03F 7/09

(52) U.S. Cl. CPC G03F 7/0035; G03F 7/167; G03F 7/2037; G03F 7/0032; G03F 7/09

(57) ABSTRACT

A method of manufacturing a semiconductor device includes forming a photoresist layer including a photoresist composition over a substrate. The photoresist layer is selectively exposed to actinic radiation. The photoresist layer is heated after selectively exposing the photoresist layer to actinic radiation. A gas is flowed over the photoresist layer during the heating the photoresist layer. A flow of the gas is varied during the heating the photoresist layer, and the photoresist layer is developed after the heating the photoresist layer to form a pattern in the photoresist layer.

### CROSS-REFERENCE TO RELATED APPLICATION

This application claims priority to U.S. Provisional Patent Application No. 63/356,423, filed Jun. 28, 2022, the entire disclosure of which is incorporated herein by reference.

### BACKGROUND

As consumer devices have gotten smaller and smaller in response to consumer demand, the individual components of these devices have necessarily decreased in size as well. Semiconductor devices, which make up a major component of devices such as mobile phones, computer tablets, and the like, have been pressured to become smaller and smaller, with a corresponding pressure on the individual devices (e.g., transistors, resistors, capacitors, etc.) within the semiconductor devices to also be reduced in size.

One enabling technology that is used in the manufacturing processes of semiconductor devices is the use of photolithographic materials. Such materials are applied to a surface of a layer to be patterned and then exposed to an energy that has itself been patterned. Such an exposure modifies the chemical and physical properties of the exposed regions of the photosensitive material. This modification, along with the lack of modification in regions of the photosensitive material that were not exposed, can be exploited to remove one region without removing the other.

However, as the size of individual devices has decreased, process windows for photolithographic processing has become tighter and tighter. As such, advances in the field of photolithographic processing are necessary to maintain the ability to scale down the devices, and further improvements are needed in order to meet the desired design criteria such that the march towards smaller and smaller components may be maintained.

As the semiconductor industry has progressed into nanometer technology process nodes in pursuit of higher device density, higher performance, and lower costs, there have been challenges in reducing semiconductor feature size. Extreme ultraviolet lithography (EUVL) has been developed to form smaller semiconductor device feature size and increase device density on a semiconductor wafer. In order to improve the efficiency of the EUVL process it is desirable to reduce the EUV exposure dose and improve the performance of the photoresist.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a process flow of manufacturing a semiconductor device according to embodiments of the disclosure.

FIG. 2 shows a process stage of a sequential operation according to an embodiment of the disclosure.

FIGS. 3A and 3B show a process stage of a sequential operation according to an embodiment of the disclosure.

FIGS. 4A, 4B, and 4C show a process stage of a sequential operation according to an embodiment of the disclosure.

FIGS. 5A and 5B show a process stage of a sequential operation according to an embodiment of the disclosure.

FIGS. 6A, 6B, and 6C show embodiments of gas showerheads according to embodiments of the disclosure.

FIG. 7 shows a semiconductor device manufacturing tool according to embodiments of the disclosure.

FIGS. 8A and 8B show an embodiment of a controller according to embodiments of the disclosure.

FIGS. 9A and 9B show a process stage of a sequential operation according to an embodiment of the disclosure.

FIGS. 10A and 10B show a process stage of a sequential operation according to embodiments of the disclosure.

FIG. 11 shows a process stage of a sequential operation according to an embodiment of the disclosure.

FIG. 12 shows a process stage of a sequential operation according to an embodiment of the disclosure.

FIG. 13 shows a process stage of a sequential operation according to an embodiment of the disclosure.

FIG. 14A shows organometallic precursors according to embodiments of the disclosure. FIG. 14B shows a reaction the organometallic precursors undergo when exposed to actinic radiation. FIG. 14C shows examples of organometallic precursors according to embodiments of the disclosure.

FIG. 15 shows a reaction the photoresist composition components undergo as a result of exposure to actinic radiation and heating according to an embodiment of the disclosure.

FIG. 16 illustrates a deposition apparatus according to embodiments of the disclosure.

FIG. 17 shows a process stage of a sequential operation according to an embodiment of the disclosure.

FIGS. 18A and 18B show process stages of a sequential operation according to embodiments of the disclosure.

FIG. 19 shows a process stage of a sequential operation according to an embodiment of the disclosure.

FIG. 20 shows a process stage of a sequential operation according to an embodiment of the disclosure.

FIG. 21 shows a process stages of a sequential operation according to an embodiment of the disclosure.

FIG. 22 is a flowchart of a method according to embodiments of the disclosure.

FIG. 23 is a flowchart of a method according to embodiments of the disclosure.

FIG. 24 is a flowchart of a method according to embodiments of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated degrees or at other orientations) and the spatially relative descriptors used herein may likewise be interpreted accordingly. In addition, the term “made of” may mean either “comprising” or “consisting of” Further, in the following fabrication process, there may be one or more additional operations in/between the described operations, and the order of operations may be changed. Materials, configurations, dimensions, processes and/or operations as explained with respect to one embodiment may be employed in the other embodiments, and the detailed description thereon may be omitted. Source/drain region(s) may refer to a source or a drain, individually or collectively dependent upon the context.

Metal-containing photoresists are desirable as high-sensitivity and high-etching selectivity photoresists. The metal particles in the metal-containing photoresists absorb high energy photons, such as extreme ultraviolet EUV photons. Metal containing photoresists include metal particles and ligands to complex the metal particles. In some embodiments, the metal particles are nanoparticles, and in some embodiments, the metal particles are metal oxide particles. In some embodiments, a metallic core including one or more metal nanoparticles is complexed by a plurality of ligand units forming a ligand-complexed metallic core.

Using metallic resists, such as tin oxide resists, can reduce the number of resist layers and the number of operations from three photolithographic and three etching operations to one photolithography and etching operations. However, EUV exposure and metallic resists may not be cost effective due to high dosage required for EUV exposure. In some embodiments of the disclosure, the chamber exhaust is optimized to enhance the photoresist crosslinking reaction during the post exposure bake (PEB) process. As a result, EUV dosage and the cost of operation (CoO) for methods according to embodiments of the disclosure are significantly reduced.

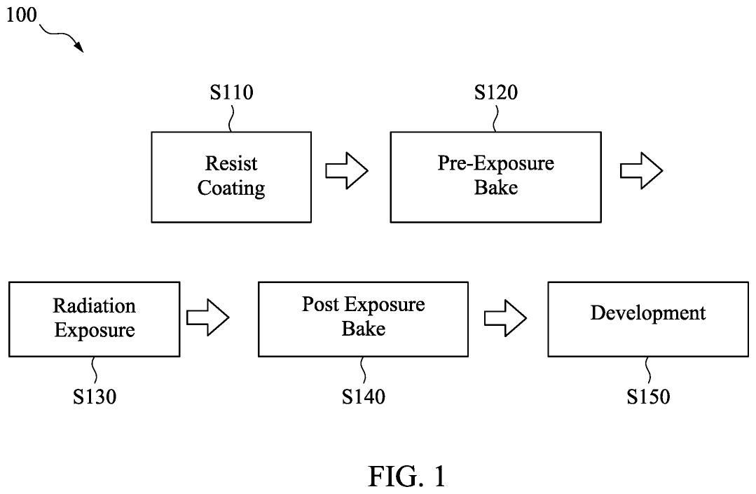

FIG. 1 illustrates a process flow 100 of manufacturing a semiconductor device according to embodiments of the disclosure. In operation S110, a resist composition is prepared. In some embodiments, the resist is a photoresist.

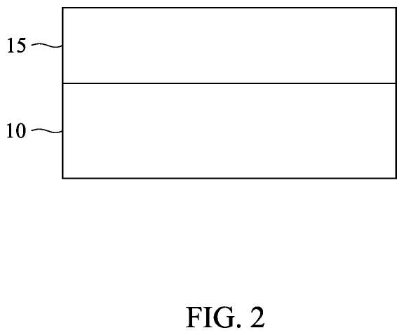

The photoresist composition is coated on a surface of a layer to be patterned or a substrate 10 in operation S110, in some embodiments, to form a resist layer 15, as shown in FIG. 2. In some embodiments, the resist layer 15 is a photoresist layer. Then, the resist layer 15 undergoes a first baking operation (or pre-exposure bake) S130 to evaporate solvents in the resist composition in some embodiments. The resist layer 15 is baked at a temperature and time sufficient to cure and dry the resist layer 15 (pre-baking). In some embodiments, the resist layer is heated to a temperature of about 40° C. to about 120° C. for about 10 seconds to about 10 minutes.

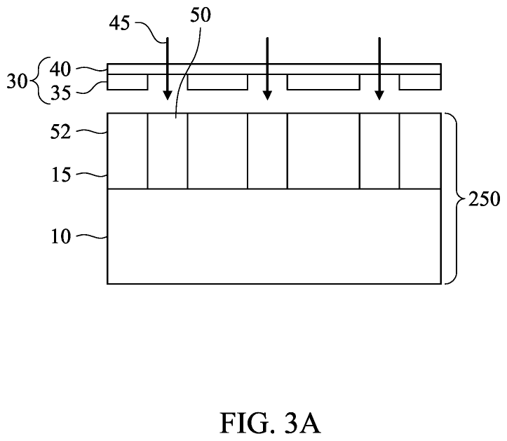

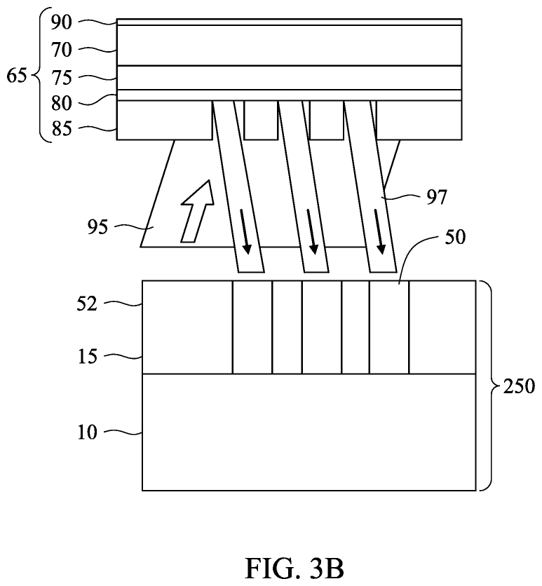

After the first (or pre-) baking operation S120, the photoresist layer 15 is selectively exposed to actinic radiation 45/97 (see FIGS. 3A and 3B) in operation S130. In some embodiments, the photoresist layer 15 is selectively exposed to ultraviolet radiation. In some embodiments, the ultraviolet radiation is deep ultraviolet radiation (DUV). In some embodiments, the ultraviolet radiation is extreme ultraviolet (EUV) radiation. In some embodiments, the actinic radiation is an electron beam.

As shown in FIG. 3A, the exposure radiation 45 passes through a photomask 30 before irradiating the photoresist layer 15 in some embodiments. In some embodiments, the photomask has a pattern to be replicated in the photoresist layer 15. The pattern is formed by an opaque pattern 35 on the photomask substrate 40, in some embodiments. The opaque pattern 35 may be formed by a material opaque to ultraviolet radiation, such as chromium, while the photomask substrate 40 is formed of a material that is transparent to ultraviolet radiation, such as fused quartz.

In some embodiments, the selective exposure of the photoresist layer 15 to form exposed regions 50 and unexposed regions 52 is performed using extreme ultraviolet lithography. In an extreme ultraviolet lithography operation, a reflective photomask 65 is used to form the patterned exposure light in some embodiments, as shown in FIG. 3B. The reflective photomask 65 includes a low thermal expansion glass substrate 70, on which a reflective multilayer 75 of Si and Mo is formed. A capping layer 80 and absorber layer 85 are formed on the reflective multilayer 75. A rear conductive layer 90 is formed on the back side of the low thermal expansion glass substrate 70. In extreme ultraviolet lithography, extreme ultraviolet radiation 95 is directed towards the reflective photomask 65 at an incident angle of about 6°. A portion 97 of the extreme ultraviolet radiation is reflected by the Si/Mo multilayer 75 towards the photoresist coated substrate 10, while the portion of the extreme ultraviolet radiation incident upon the absorber layer 85 is absorbed by the photomask. In some embodiments, additional optics, including mirrors, are between the reflective photomask 65 and the photoresist coated substrate.

The region of the photoresist layer exposed to radiation 50 undergoes a chemical reaction thereby changing its solubility in a subsequently applied developer relative to the region of the photoresist layer not exposed to radiation 52. In some embodiments, the portion of the photoresist layer exposed to radiation 50 undergoes a crosslinking reaction.

Next, the photoresist layer 15 undergoes a second baking operation (or post exposure bake) in operation S140. In some embodiments, the photoresist layer 15 is heated to a temperature of about 70° C. to about 220° C. for about 20 seconds to about 200 seconds. The post exposure baking may be used in order to assist in the generating, dispersing, and reacting of the acid/base/free radical generated from the impingement of the radiation 45/97 upon the photoresist layer 15 during the exposure or to enhance crosslinking of the radiation exposed regions 50 of the photoresist layer. Such assistance helps to create or enhance chemical reactions, which generate chemical differences between the exposed region 50 and the unexposed region 52 within the photoresist layer. These chemical differences also cause differences in the solubility between the exposed region 50 and the unexposed region 52.

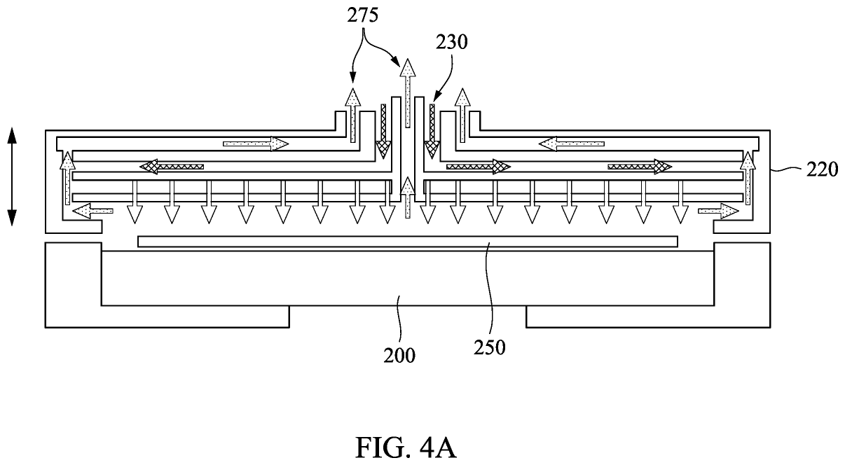

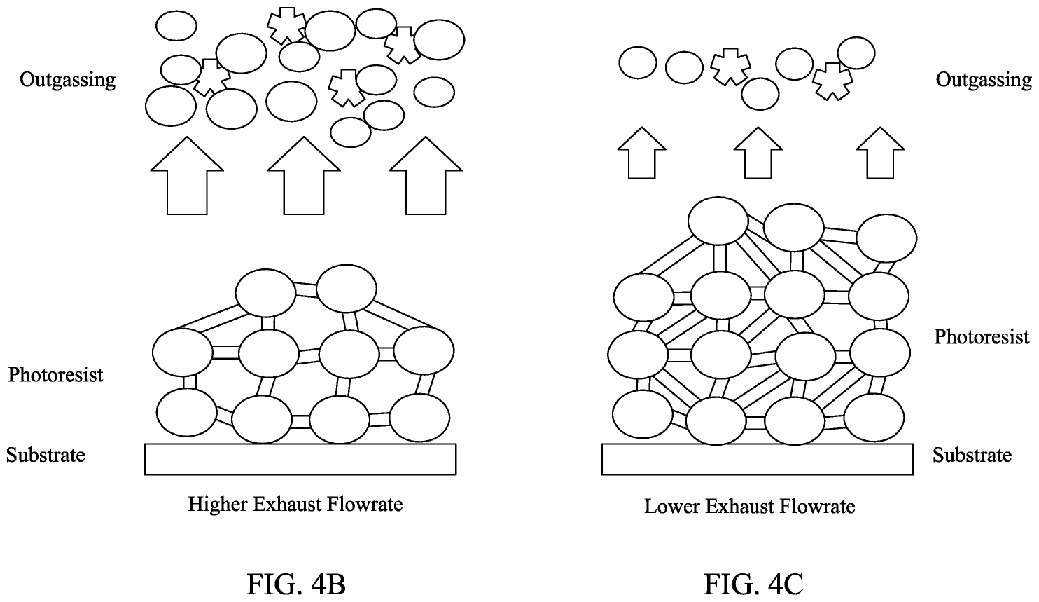

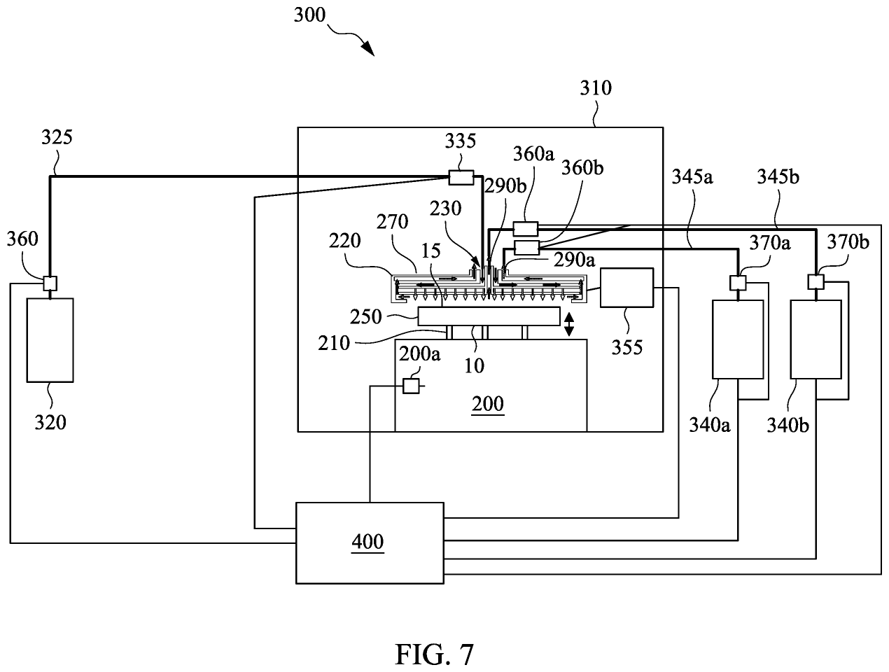

FIGS. 4A, 4B, and 4C illustrate the post exposure baking operation according to embodiments of the disclosure. FIGS. 4A, 4B, and 4C show a photoresist coated substrate 250 undergoing a post-exposure bake (or heating) operation. The photoresist coated substrate 250 is placed over a heating element 200 (e.g., an electric heater). In some embodiments, the heating element 200 is a hot plate. In some embodiments, the photoresist coated substrate 250 is supported by support pins 210 (see FIG. 7) over the heating element 200. A manifold 220 with an purge gas flow 230 is located above the photoresist coated substrate 250. The purge gas is subsequently exhausted 275 from the manifold at either a central portion of the manifold or an edge portion of the manifold, as shown in FIG. 4A. The purge gas purges outgassing from the photoresist layer during the post exposure bake. In some embodiments, the purge gas is clean dry air (CDA); carbon dioxide; an inert gas, including nitrogen, helium, neon, and argon; or combinations thereof.

The manifold 220 is lowered relative to the photoresist coated substrate 250 so that the purge gas 230 flows over the photoresist coated substrate 250 in some embodiments, as shown in FIG. 4A. In some embodiments, the photoresist coated substrate 250 is raised toward the manifold by the support pins 210.

In some embodiments during the post exposure baking (heating), the photoresist layer 15 is heated at a temperature in a range of about 70° C. to about 220° C. by controlling the temperature of the heating element 200. In some embodiments, during the post exposure baking (heating), the photoresist layer 15 is heated at a temperature in a range of about 100° C. to about 200° C. In some embodiments, during the post exposure baking, the photoresist layer 15 is heated at a temperature in a range of about 150° C. to about 190° C. Heating at temperatures below the recited ranges may result in insufficient crosslinking of the exposed portions of the photoresist layer and insufficient removal of reaction byproducts. Heating the photoresist layer at temperatures above the recited ranges may damage the photoresist layer or other layers of the semiconductor device, or unnecessarily increase the cost of the semiconductor device manufacturing process.

In some embodiments, during the post exposure baking, the photoresist layer 15 is heated for about 40 seconds to about 200 seconds. In some embodiments, the photoresist layer 15 is heated for about 65 seconds to about 175 seconds. Heating the photoresist layer for a time period less than the recited ranges may result in insufficient crosslinking of the exposed portions of the photoresist layer and insufficient removal of reaction byproducts. Heating the photoresist layer for a time period greater than the recited ranges may damage the photoresist layer or other layers of the semiconductor device, or decrease the yield of semiconductor devices.

In some embodiments, the exhaust flowrate of the purge gas is controlled to provide increased crosslinking of the photoresist layer and increased removal of the photoresist outgassing. As shown in FIG. 4B, at higher exhaust gas flowrates, a greater amount of outgassing, reaction byproducts, and contaminants are removed from photoresist layer and the processing chamber. However, during the post exposure baking operation, crosslinking reactants may also be removed with the exhaust gas, resulting in thinner photoresist layers with a reduced amount of crosslinking, as shown in FIG. 4B. On the other hand, at lower exhaust flowrates, more crosslinking reactants remain in the photoresist layer, and a greater amount of crosslinking occurs in the radiation exposed regions of the photoresist layer, as shown in FIG. 4C. However, at lower exhaust gas flowrates, less outgassing of reaction byproducts occurs, which may result in contamination of the processing chamber and the semiconductor device. Therefore, it is desirable to control the exhaust gas flowrate so that crosslinking and contaminant removal are optimized. In embodiments of the present disclosure, the exhaust gas flowrate and post exposure baking parameters are controlled to optimize the photoresist layer crosslinking and contaminant reduction.

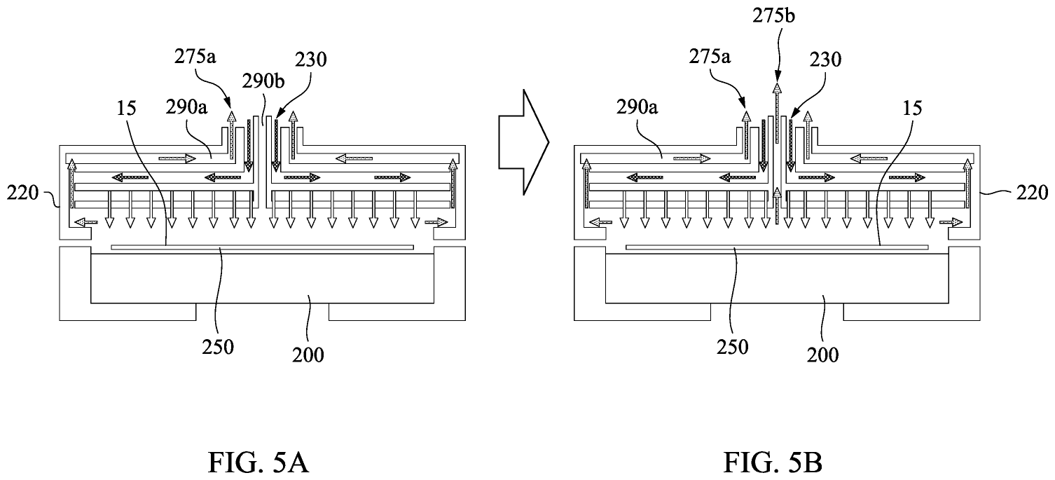

In some embodiments, the flow of purge gas 230 over the photoresist layer 15 is varied during the post exposure baking operation. In some embodiments, as shown in FIG. 5A, the purge gas is exhausted from only gas exhausts 290a located at the edge portion of the manifold 220 during a first time period of flowing the gas 230 over the photoresist layer 15, and then, as shown in FIG. 5B, the gas 275a, 275b is exhausted from the gas exhausts 290a located at the edge portion and a gas exhaust 290b located at the central portion of the manifold 220 during a second time period of flowing gas 230 over the photoresist layer 15. In some embodiments, the first time period is longer than the second time period. In some embodiments, the first time period ranges from about 40 seconds to about 200 seconds, and the second time period ranges from about 2 seconds to about 85 seconds. In other embodiments, the first time period ranges from about 60 seconds to about 115 seconds, and the second time period ranges from about 5 seconds to about 60 seconds.

In some embodiments, a flowrate of the gas 230 supplied to the space over the photoresist layer 15 ranges from about 1 L/min to about 20 L/min, an exhaust flowrate of the gas 275a through the gas exhausts 290a located at the edge portion of the manifold 220 ranges from about 1 L/min to about 20 L/min during the first time period and the second time period, as shown in FIGS. 5A and 5B, while there is no gas exhausted through the gas exhaust 290b in the central portion of the manifold 220 (flowrate=0), as shown in FIG. 5A. Then in FIG. 5B, the exhaust flowrate of the gas 275b through the gas exhaust 290b located at the central portion of the manifold 220 ranges from about 10 L/min to about 80 L/min during the second time period, while the flowrates of the incoming gas 230 and the exhaust gas 275a through the gas exhausts 290a at the edge portion of the manifold 220 are maintained at about 1 L/min to about 20 L/min. In some embodiments, the flowrate of the incoming gas 230 supplied to the space over the photoresist layer 15 ranges from about 2 L/min to about 10 L/min, a flowrate of the gas 275a through the gas exhausts 290a located at the edge portion of the manifold 220 ranges from about 2 L/min to about 10 L/min during the first time period and the second time period, and the flowrate of the gas 275b through the gas exhaust 290b located at the central portion of the manifold 220 ranges from about 20 L/min to about 60 L/min during the second time period. In some embodiments, the flowrate of the gas 275b through the gas exhaust 290b located at the central portion of the manifold 220 during the second time period is greater than the flowrate of the gas 275a through the gas exhausts located at the edge portion of the manifold 220. In some embodiments, the flowrate of the gas 275b through the gas exhaust 290b located at the central portion of the manifold 220 during the second time period is greater than the flowrate of the incoming purge gas 230 supplied through the manifold 220.

In some embodiments, a ratio of the flowrate F2C of the exhaust gas 275b flowing through the gas exhaust 290b in the central portion of the manifold 220 to the flowrate F2E of the exhaust gas 275a flowing through the gas exhausts 290a at the edge portion of the manifold ranges from about 1 to about 80 during the second time period, in other embodiments the ratio F2C/F2E ranges from about 2 to about 30. In some embodiments, a ratio of the flowrate F2C of the exhaust gas 275b flowing through the gas exhaust 290b in the central portion of the manifold 220 to the flowrate F1 of the incoming gas 230 ranges from about 1 to about 80 during the second time period, in other embodiments the ratio F2C/F1 ranges from about 2 to about 30. In some embodiments a ratio of flowrate F1 of the incoming gas to the flowrate FE of the exhaust gas 275a flowing through the edge portions 290a of the manifold during either the first or second time period ranges from about 0.2 to about 5. In some embodiments, the ratio F1/FE is about 1.

In some embodiments, a ratio of the second time period P2 to the first time period P1 ranges from about 0.01 to about 1. In other embodiments, the ratio of the second time period to the first time period ranges from about 0.04 to about 0.5.

Incoming gas flowrates 230 and exhaust gas flowrates 275a, 275b outside the disclosed ranges or ratios may result in insufficient crosslinking of the exposed portions of the photoresist layer and insufficient removal of reaction byproducts. Similarly, lengths of the first and second time periods outside the disclosed ranges or ratios may also result in insufficient crosslinking of the exposed portions of the photoresist layer and insufficient removal of reaction byproducts.

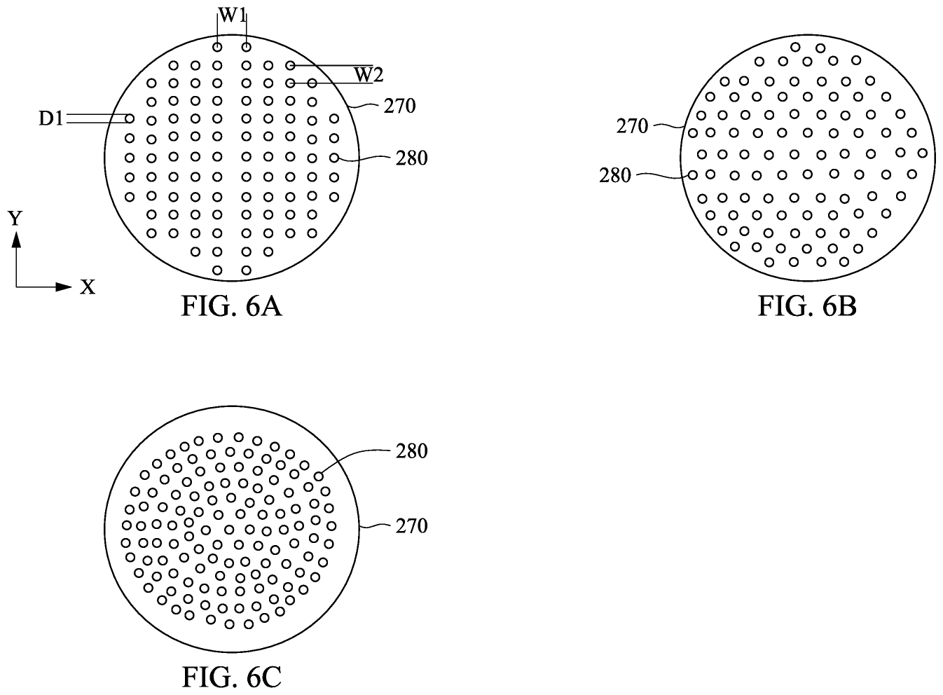

In some embodiments, a gas showerhead 270 is used as the manifold, as shown in plan view in FIGS. 6A-6C. In some embodiments, the use of the gas showerhead 270 minimizes turbulence of the incoming purge gas flow 230, and provides improved temperature control over the photoresist coated substrate 250.

In an embodiment, a surface of the showerhead 270 facing the photoresist layer 15 on the photoresist coated substrate 250 is spaced-apart from the main surface of the photoresist layer by a distance ranging from about 1 mm to about 25 mm. In some embodiments, the surface of the showerhead 270 facing the photoresist layer 15 is spaced-apart from the main surface of the photoresist layer 15 by a distance ranging from about 3 mm to about 15 mm.

In some embodiments, the showerhead 270 includes a plurality of openings 280 through which the gas flows, as shown in FIGS. 6A-6C. As shown in FIG. 6A, in some embodiments, the plurality of openings are arranged in a row and column arrangement. In some embodiments, each of the plurality of openings 280 has a diameter D1 ranging from about 0.1 mm to about 10 mm. In some embodiments, each of the plurality of openings 280 has a diameter D1 ranging from about 1 mm to about 5 mm. In some embodiments, the diameter D1 of the plurality of openings 280 is about 2 mm. In some embodiments, the plurality of openings 180 have a pitch W1, W2 along the X-direction and the Y-direction ranging from about 0.5 mm to about 24 mm. In some embodiments, the plurality of openings 280 have a pitch ranging from about 3 mm to about 10 mm. In some embodiments, the plurality of openings 280 have a pitch of about 6 mm. In some embodiments, the pitch in the X direction and the pitch in the Y direction are about the same, in other embodiments, the pitch in the X direction and the Y direction are different. Openings having a pitch outside the ranges disclosed herein may result in photoresist patterns having decreased critical dimension uniformity and increased line width roughness.

In some embodiments, gas showerheads 270 having other patterns of openings 280 are included. As shown in FIG. 6B, in some embodiments, the plurality of openings 280 are arranged in lines, where openings 280 in alternating lines are staggered relative to immediately adjacent lines. In another embodiment, the openings 280 are arranged in concentric circles surrounding a central opening, as shown in FIG. 6C. In some embodiments, the diameter D1 of the openings 280 closer to the center of the gas showerhead 270 is larger than the diameter D1 of the openings 280 closer to the periphery of the gas showerhead 270. The patterns of openings 280 are not limited to the embodiments shown herein. In other embodiments, other patterns, such as a spiral pattern, random pattern, etc. are within the scope of this disclosure.

A semiconductor device manufacturing tool 300 according to some embodiments of this disclosure is illustrated in FIG. 7. In some embodiments, the semiconductor device manufacturing tool 300 includes a processing chamber 310, such as a post exposure baking chamber. A heating element 200 is disposed inside the chamber. In some embodiments, a plurality of support pins 210 is disposed inside the chamber 310. The plurality of support pins 210 is configured to support a photoresist coated semiconductor substrate 250 over the heating element 200. The plurality of support pins 210 are configured to raise and lower the semiconductor substrate 250. A gas showerhead 270 is disposed over the heating element in some embodiments. A manifold raising/lowering mechanism 355 raises and lowers the manifold 220 in some embodiments. In other embodiments, other types of gas manifolds are used, such as the gas manifold 220 illustrated in FIGS. 4A, 5A, 5B, and 9A-10B.

In some embodiments, the semiconductor device manufacturing tool 300 includes a purge gas source 320. The gas source 320 is connected to the manifold 220 by a gas distribution line 325. The gas source 320 supplies the purge gas 230 to the manifold. In some embodiments, a first vacuum pump 340a is connected to the gas exhausts 290a located at the peripheral (edge) portions of the manifold 220 through a first vacuum line 345a, and a second vacuum pump 340b is connected to the gas exhaust 290b located at the central portion of the manifold 220 through a second vacuum line 345b. The vacuum pumps 340a, 340b are used to exhaust the purge gas, photoresist outgassing, and contaminants after the purge gas flows over the photoresist coated substrate 250.

In some embodiments, a controller 400 is configured to control any or all of the flowrate of the purge gas 230 gas supplied through the gas manifold 220, the flowrate of the exhaust gas 275a flowing through the gas exhausts 290a at the peripheral (edge) portion of the gas manifold 220, the flowrate of the exhaust gas 275 flowing through the gas exhaust 290b at the central portion of the gas manifold 220, the temperature of the heating element 200; the motion of the plurality of the support pins 210 along a vertical direction, and the motion of the gas manifold 220 along the vertical direction in some embodiments, as shown in FIG. 7. In some embodiments, the controller 400 controls a mechanism 355 for raising and lowering the gas manifold 220. In some embodiments, adjustable valves 365, 370a, and 370b are in the gas distribution line 325 and the vacuum lines 345a, 345b, respectively, which are controlled by the controller 400. Thus, in some embodiments, the controller can shut off the vacuum to either of the first vacuum line 345a or the second vacuum line 345b, thus shutting off the exhaust gas flow through either of the gas exhausts at the edge portions 290a or the at the central portion 290b of the manifold 220 during the post exposure bake operation S140. In some embodiments, the controller 400 communicates with a temperature sensor 200a, and determines whether to increase or decrease the temperature of the heating element 200.

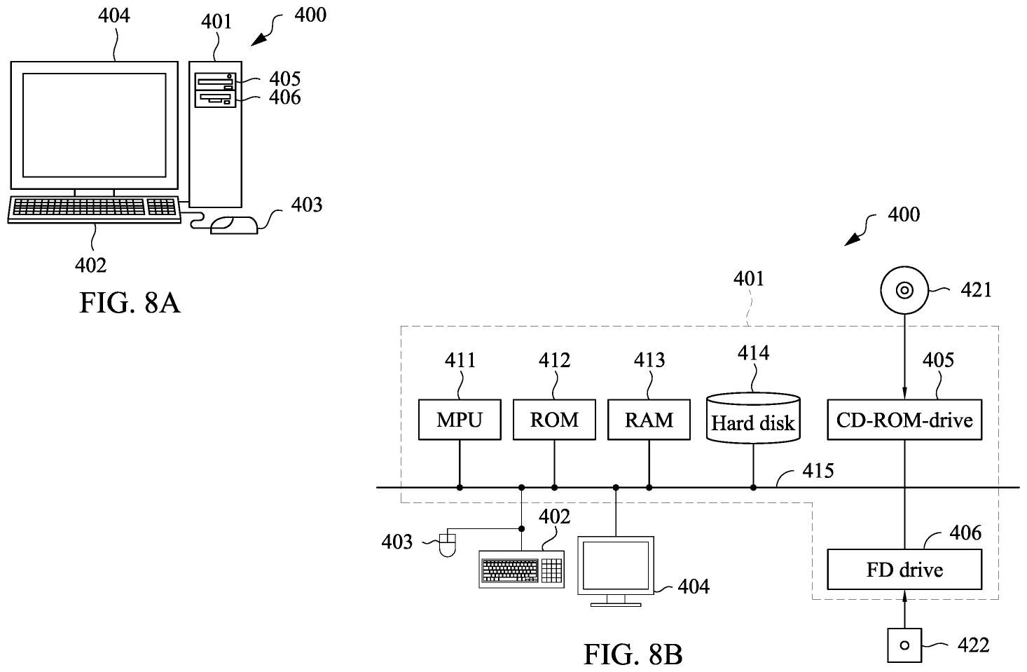

All of or a part of the methods or operations of the foregoing embodiments are realized using computer hardware and special purpose computer programs executed thereon. In FIG. 8A, an embodiment of the controller 400 is illustrated. The controller 400 is a computer system 400 provided with a computer 401 including an optical disk read only memory (e.g., CD-ROM or DVD-ROM) drive 405 and a magnetic disk drive 406, a keyboard 402, a mouse 403, and a monitor 404 in some embodiments.

FIG. 8B is a diagram showing an internal configuration of the computer system 400 in some embodiments. In FIG. 8B, the computer 401 is provided with, in addition to the optical disk drive 405 and the magnetic disk drive 406, one or more processors 411, such as a micro-processor unit (MPU); a ROM 412 in which a program such as a boot up program is stored; a random access memory (RAM) 413 connected to the processors 411 and in which a command of an application program is temporarily stored and a temporary electronic storage area is provided; a hard disk 414 in which an application program, an operating system program, and data are stored; and a data communication bus 415 that connects the processors 411, the ROM 412, and the like. Note that the computer 401 may include a network card (not shown) for providing a connection to a computer network such as a local area network (LAN), wide area network (WAN) or any other useful computer network for communicating data used by the computing system 400.

The program for causing the computer system 400 to execute the process for controlling the apparatus of FIG. 7 and/or to execute the process for the method of manufacturing a semiconductor device according to the embodiments disclosed herein are stored in an optical disk 421 or a magnetic disk 422, which are inserted into the optical disk drive 405 or the magnetic disk drive 406, and transmitted to the hard disk 414. Alternatively, the program may be transmitted via a network (not shown) to the computer system 400 and stored in the hard disk 414. At the time of execution, the program is loaded into the RAM 413. The program may be loaded from the optical disk 421 or the magnetic disk 422, or directly from a network. The stored programs do not necessarily have to include, for example, an operating system (OS) or a third-party program to cause the computer 401 to execute the methods disclosed herein. The program includes a command portion to call an appropriate function (module) in a controlled mode and obtain desired results in some embodiments.

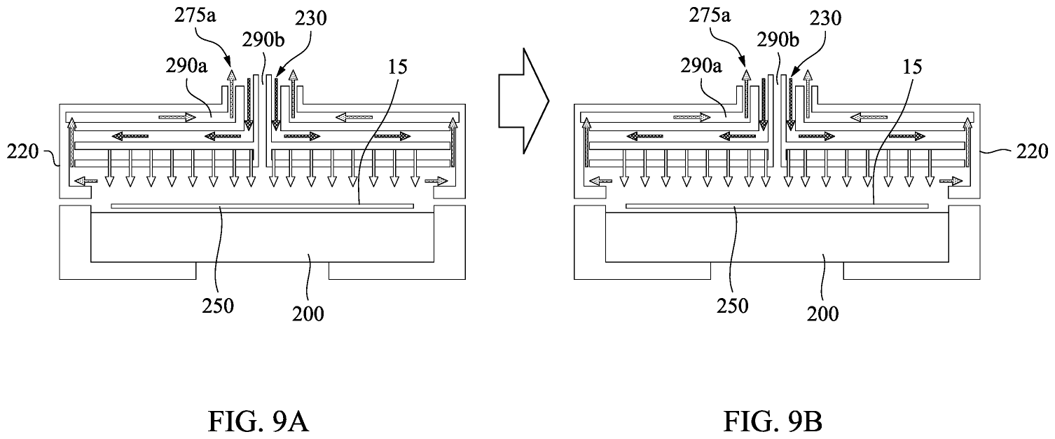

Another embodiment of the post exposure bake operation S140 is illustrated in FIGS. 9A and 9B. In this embodiment, a flowrate of the gas 230 supplied to the space over the photoresist layer 15 ranges from about 1 L/min to about 20 L/min during the first time period and an exhaust flowrate of the gas 275a through the gas exhausts 290a located at the edge portion of the manifold 220 ranges from about 1 L/min to about 20 L/min during the first time period, while there is no gas exhausted through the gas exhaust 290b in the central portion of the manifold 220 (flowrate=0), as shown in FIG. 9A. Then in FIG. 9B, the exhaust flowrate of the gas 275a through the gas exhausts 290a located at the edge portion of the manifold 220 ranges from about 10 L/min to about 80 L/min during the second time period, while the flowrate of the incoming gas 230 is maintained at about 1 L/min to about 20 L/min, and there is no exhaust gas flow through the gas exhaust 290b in the central portion of the manifold 220. In some embodiments, the flowrate of the incoming gas 230 supplied to the space over the photoresist layer 15 ranges from about 2 L/min to about 10 L/min, the flowrate of the gas 275a through the gas exhausts 290a located at the edge portion of the manifold 220 ranges from 2 L/min to 10 L/min during the first time period, and the flowrate of the gas 275a through the gas exhausts 290a located at the edge portions of the manifold 220 ranges from 20 L/min to 60 L/min during the second time period. In some embodiments, the flowrate of the gas 275a through the gas exhausts 290a located at the edge portion of the manifold 220 during the second time period is greater than the flowrate of the incoming gas 230 supplied through the manifold 220 during the second time period.

In some embodiments, a ratio of the flowrate F2E of the exhaust gas 275a flowing through the gas exhausts 290a at the edge portion of the manifold 220 during the second time period to the flowrate F1E of the exhaust gas 275a flowing through the gas exhausts 290a at the edge portion of the manifold during the first time period ranges from about 1 to about 80, in other embodiments the ratio F2E/F1E ranges from about 2 to about 30. In some embodiments, a ratio of the flowrate F2E of the exhaust gas 275a flowing through the gas exhausts 290a at the edge portion of the manifold 220 to the flowrate F1 of the incoming gas 230 ranges from about 1 to about 80 during the second time period, in other embodiments the ratio F2E/F1 ranges from about 2 to about 30. In some embodiments a ratio of flowrate F1 of the incoming gas 230 to the flowrate F1E of the exhaust gas 275a flowing through the edge portions 290a of the manifold during the first time period ranges from about 0.2 to about 5. In some embodiments, the ratio F1/F1E is about 1.

In some embodiments, a ratio of the second time period P2 to the first time period P1 ranges from about 0.01 to about 1. In other embodiments, the ratio of the second time period to the first time period ranges from about 0.04 to about 0.5.

Incoming gas flowrates 230 and exhaust gas flowrates 275a outside the disclosed ranges or ratios may result in insufficient crosslinking of the exposed portions of the photoresist layer and insufficient removal of reaction byproducts. Similarly, lengths of the first and second time periods outside the disclosed ranges or ratios may also result in insufficient crosslinking of the exposed portions of the photoresist layer and insufficient removal of reaction byproducts.

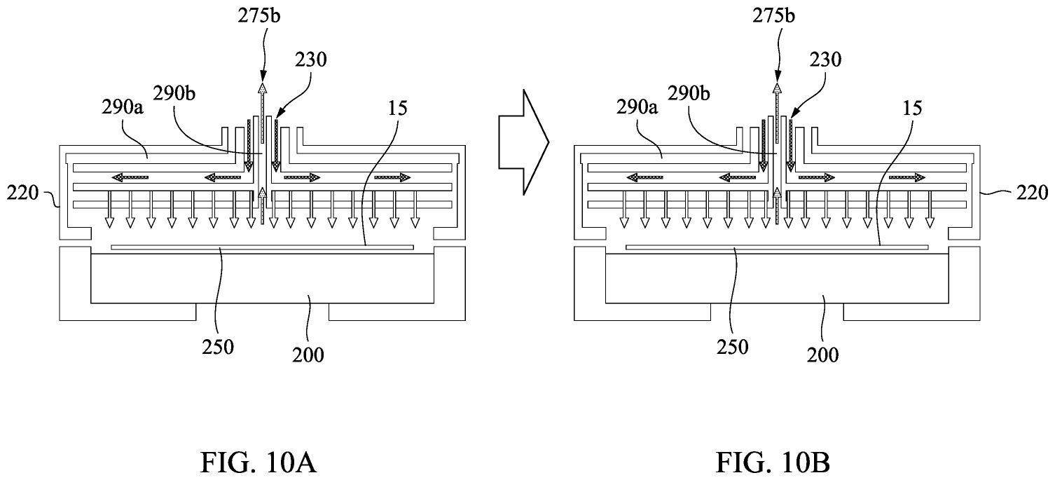

Another embodiment of the post exposure bake operation S140 is illustrated in FIGS. 10A and 10B. In this embodiment, a flowrate of the gas 230 supplied to the space over the photoresist layer 15 ranges from about 1 L/min to about 20 L/min during the first time period and an exhaust flowrate of the gas 275b through the gas exhaust 290b located in the central portion of the manifold 220 ranges from about 1 L/min to about 20 L/min during the first time period, while there is no gas exhausted through the gas exhausts 290a at the edge portion of the manifold 220 (flowrate=0), as shown in FIG. 10A. Then in FIG. 9B, the exhaust flowrate of the gas 275b through the gas exhaust 290b located in the central portion of the manifold 220 ranges from about 10 L/min to about 80 L/min during the second time period, while the flowrate of the incoming gas 230 is maintained at about 1 L/min to about 20 L/min and there is no exhaust gas flow through the gas exhausts 290a at the edge portions of the manifold 220. In some embodiments, the flowrate of the incoming gas 230 supplied to the space over the photoresist layer 15 ranges from about 2 L/min to about 10 L/min, the flowrate of the gas 275b through the gas exhausts 290b located in the central portion of the manifold 220 ranges from 2 L/min to 10 L/min during the first time period, and the flowrate of the gas 275b through the gas exhaust 290b located in the central portion of the manifold 220 ranges from 20 L/min to 60 L/min during the second time period. In some embodiments, the flowrate of the exhaust gas 275b through the gas exhausts 290b located in the central portion of the manifold 220 during the second time period is greater than the flowrate of the incoming gas 230 supplied through the manifold 220 during the second time period.

In some embodiments, a ratio of the flowrate F2C of the exhaust gas 275b flowing through the gas exhaust 290b in the central portion of the manifold 220 during the second time period to the flowrate F1C of the exhaust gas 275b flowing through the gas exhaust 290b in the central portion of the manifold during the first time period ranges from about 1 to about 80, in other embodiments the ratio F2C/F1C ranges from about 2 to about 30. In some embodiments, a ratio of the flowrate F2C of the exhaust gas 275b flowing through the gas exhausts 290b in the central portion of the manifold 220 to the flowrate F1 of the incoming gas 230 ranges from about 1 to about 80 during the second time period, in other embodiments the ratio F2C/F1 ranges from about 2 to about 30. In some embodiments a ratio of flowrate F1 of the incoming gas to the flowrate F1C of the exhaust gas 275b flowing through the central portion 290b of the manifold during the first time period ranges from about 0.2 to about 5. In some embodiments, the ratio F1/F1C is about 1.

In some embodiments, a ratio of the second time period P2 to the first time period P1 ranges from about 0.01 to about 1. In other embodiments, the FIG. of the second time period to the first time period ranges from about 0.04 to about 0.5.

Incoming gas flowrates 230 and exhaust gas flowrates 275b outside the disclosed ranges or ratios may result in insufficient crosslinking of the exposed portions of the photoresist layer and insufficient removal of reaction byproducts. Similarly, lengths of the first and second time periods outside the disclosed ranges or ratios may also result in insufficient crosslinking of the exposed portions of the photoresist layer and insufficient removal of reaction byproducts.

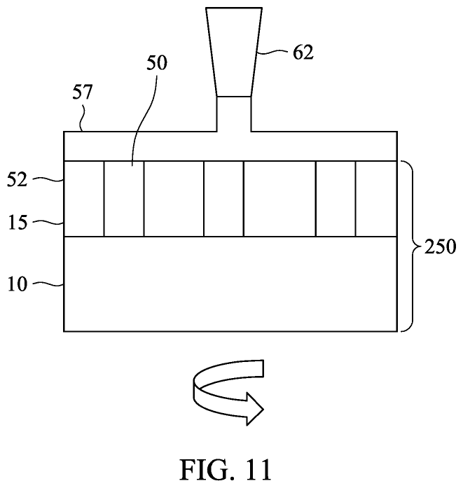

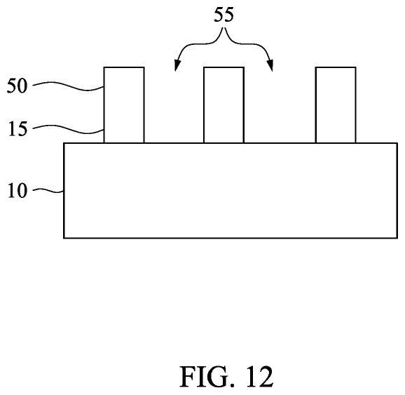

The selectively exposed photoresist layer is subsequently developed by applying a developer to the selectively exposed photoresist layer in operation S150. As shown in FIG. 11, a developer 57 is supplied from a dispenser 62 to the photoresist layer 15. In some embodiments, where the photoresist is a negative-tone resist, the unexposed portion of the photoresist layer 52 is removed by the developer 57 forming a pattern of openings 55 in the photoresist layer 15 to expose the substrate 10, as shown in FIG. 12.

In some embodiments, the pattern of openings 55a in the photoresist layer 15 are extended into the layer to be patterned or substrate 10 to create a pattern of openings 55′ in the substrate 10, thereby transferring the pattern in the photoresist layer 15 into the substrate 10, as shown in FIG. 11. The pattern is extended into the substrate by etching, using one or more suitable etchants. The portion of the photoresist layer 15 remaining after the development operation is at least partially removed during the etching operation in some embodiments. In other embodiments, the remaining photoresist layer 15 is removed after etching the substrate 10 by using a suitable photoresist stripper solvent or by a photoresist ashing operation.

In some embodiments, the substrate 10 includes a single crystalline semiconductor layer on at least it surface portion. The substrate 10 may include a single crystalline semiconductor material such as, but not limited to Si, Ge, SiGe, GaAs, InSb, GaP, GaSb, InAlAs, InGaAs, GaSbP, GaAsSb and InP. In some embodiments, the substrate 10 is a silicon layer of an SOI (silicon-on insulator) substrate. In certain embodiments, the substrate 10 is made of crystalline Si.

The substrate 10 may include in its surface region, one or more buffer layers (not shown). The buffer layers can serve to gradually change the lattice constant from that of the substrate to that of subsequently formed source/drain regions. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In an embodiment, the silicon germanium (SiGe) buffer layer is epitaxially grown on the silicon substrate 10. The germanium concentration of the SiGe buffer layers may increase from 30 atomic % for the bottom-most buffer layer to 70 atomic % for the top-most buffer layer.

In some embodiments, the substrate 10 includes one or more layers of at least one metal, metal alloy, and metal nitride/sulfide/oxide/silicide having the formula MXₐ, where M is a metal and X is N, S, Se, O, Si, and a is from about 0.4 to about 2.5. In some embodiments, the substrate 10 includes titanium, aluminum, cobalt, ruthenium, titanium nitride, tungsten nitride, tantalum nitride, or combinations thereof.

In some embodiments, the substrate 10 includes a dielectric having at least a silicon or metal oxide or nitride of the formula MX_{b}, where M is a metal or Si, X is N or O, and b ranges from about 0.4 to about 2.5. In some embodiments, the substrate 10 includes silicon dioxide, silicon nitride, aluminum oxide, hafnium oxide, lanthanum oxide, or combinations thereof.

In some embodiments, the substrate 10 refers to any underlying layers over which a resist layer is formed. The substrate 10 is subsequently patterned using photolithographic and etching operations.

The photoresist layer 15 is a photosensitive layer that is patterned by exposure to actinic radiation. Typically, the chemical properties of the photoresist regions struck by incident radiation change in a manner that depends on the type of photoresist used. Photoresist layers 15 are either positive-tone resists or negative tone-resists. A positive-tone resist refers to a photoresist material that when exposed to radiation, such as UV light, becomes soluble in a developer, while the region of the photoresist that is non-exposed (or exposed less) is insoluble in the developer. A negative-tone resist, on the other hand, refers to a photoresist material that when exposed to radiation becomes insoluble in the developer, while the region of the photoresist that is non-exposed (or exposed less) is soluble in the developer. The region of a negative resist that becomes insoluble upon exposure to radiation may become insoluble due to a cross-linking reaction caused by the exposure to radiation.

Whether a resist is a positive-tone or negative-tone may depend on the type of developer used to develop the resist. For example, some positive tone photoresists provide a positive pattern, (i.e.—the exposed regions are removed by the developer), when the developer is an aqueous-based developer, such as a tetramethylammonium hydroxide (TMAH) solution. On the other hand, the same photoresist provides a negative pattern (i.e.—the unexposed regions are removed by the developer) when the developer is an organic solvent. Further, in some negative-tone photoresists developed with the TMAH solution, the unexposed regions of the photoresist are removed by the TMAH, and the exposed regions of the photoresist, that undergo cross-linking upon exposure to actinic radiation, remain on the substrate after development.

Resist compositions according to the present disclosure are metal-containing resists. In some embodiments, the photoresist layer 15 is a negative tone metallic photoresist that undergoes a cross-linking reaction upon exposure to the radiation.

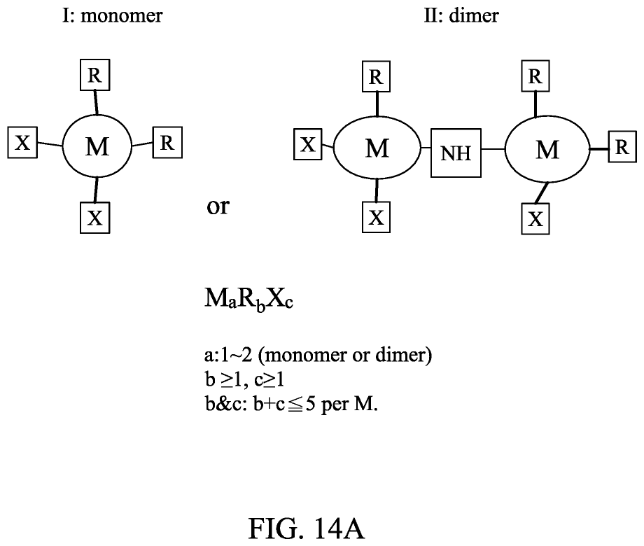

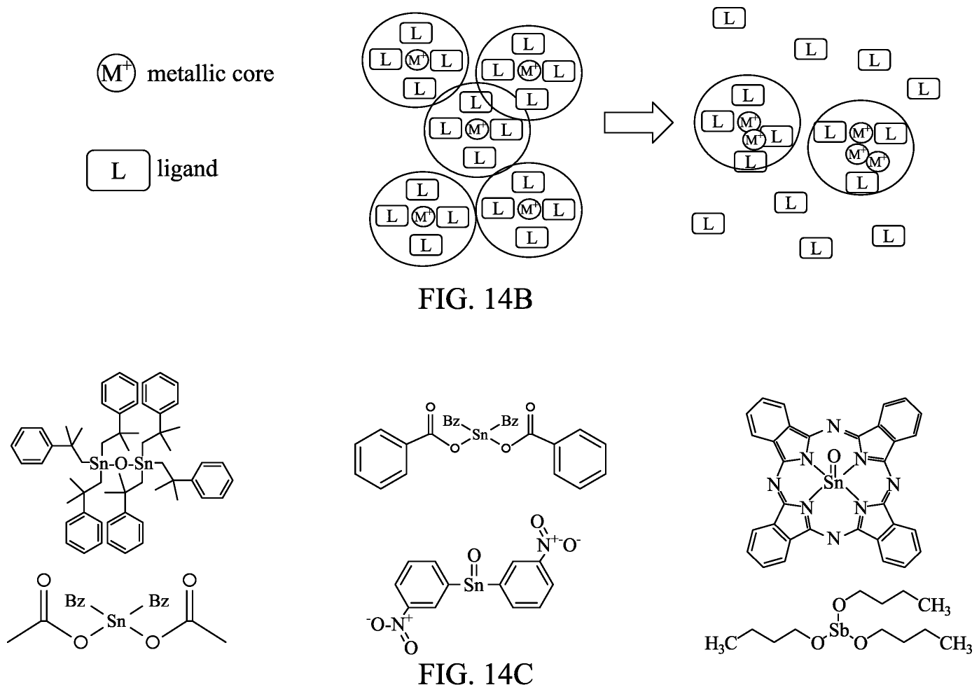

In some embodiments, the photoresist layer 15 is made of a metallic photoresist composition, including a first compound or a first precursor and a second compound or a second precursor combined in a vapor state. The first precursor or first compound is an organometallic having a formula: MₐR_{b}X_{c}, as shown in FIG. 14A, where M is at least one of Sn, Bi, Sb, In, Te, Ti, Zr, Hf, V, Co, Mo, W, Al, Ga, Si, Ge, P, As, Y, La, Ce, or Lu; and R is a substituted or unsubstituted alkyl, alkenyl, or carboxylate group. In some embodiments, M is selected from the group consisting of Sn, Bi, Sb, In, Te, and combinations thereof. In some embodiments, R is a C3-C6 alkyl, alkenyl, or carboxylate. In some embodiments, R is selected from the group consisting of propyl, isopropyl, butyl, iso-butyl, sec-butyl, tert-butyl, pentyl, isopentyl, sec-pentyl, tert-pentyl, hexyl, iso-hexyl, sec-hexyl, tert-hexyl, and combinations thereof. X is a ligand, ion, or other moiety, which is reactive with the second compound or second precursor; and 1≤a≤2, b≥1, c≥1, and b+c≤5 in some embodiments. In some embodiments, the alkyl, alkenyl, or carboxylate group is substituted with one or more fluoro groups. In some embodiments, the organometallic precursor is a dimer, as shown in FIG. 14A, where each monomer unit is linked by an amine group. Each monomer has a formula: MₐR_{b}X_{c}, as defined above.

In some embodiments, R is alkyl, such as CₙH₂ₙ₊₁ where n≥3. In some embodiments, R is fluorinated, e.g., having the formula CₙFₓH₍₍₂ₙ₊₁₎₋ₓ₎. In some embodiments, R has at least one beta-hydrogen or beta-fluorine. In some embodiments, R is selected from the group consisting of i-propyl, n-propyl, t-butyl, i-butyl, n-butyl, sec-butyl, n-pentyl, i-pentyl, t-pentyl, and sec-pentyl, and combinations thereof.

In some embodiments, X is any moiety readily displaced by the second compound or second precursor to generate an M-OH moiety, such as a moiety selected from the group consisting of amines, including dialkylamino and monalkylamino; alkoxy; carboxylates, halogens, and sulfonates. In some embodiments, the sulfonate group is substituted with one or more amine groups. In some embodiments, the halide is one or more selected from the group consisting of F, Cl, Br, and I. In some embodiments, the sulfonate group includes a substituted or unsubstituted C1-C3 group.

In some embodiments, the first organometallic compound or first organometallic precursor includes a metallic core M⁺ with ligands L attached to the metallic core M⁺, as shown in FIG. 14B. In some embodiments, the metallic core M⁺ is a metal oxide. The ligands L include C3-C12 aliphatic or aromatic groups in some embodiments. The aliphatic or aromatic groups may be unbranched or branched with cyclic, or noncyclic saturated pendant groups containing 1-9 carbons, including alkyl groups, alkenyl groups, and phenyl groups. The branched groups may be further substituted with oxygen or halogen. In some embodiments, the C3-C12 aliphatic or aromatic groups include heterocyclic groups. In some embodiments, the C3-C12 aliphatic or aromatic groups are attached to the metal by an ether or ester linkage. In some embodiments, the C3-C12 aliphatic or aromatic groups include nitrite and sulfonate substituents.

In some embodiments, the organometallic precursor or organometallic compound include a sec-hexyl tris(dimethylamino) tin, t-hexyl tris(dimethylamino) tin, i-hexyl tris(dimethylamino) tin, n-hexyl tris(dimethylamino) tin, sec-pentyl tris(dimethylamino) tin, t-pentyl tris(dimethylamino) tin, i-pentyl tris(dimethylamino) tin, n-pentyl tris(dimethylamino) tin, sec-butyl tris(dimethylamino) tin, t-butyl tris(dimethylamino) tin, i-butyl tris(dimethylamino) tin, n-butyl tris(dimethylamino) tin, sec-butyl tris(dimethylamino) tin, i-propyl(tris)dimethylamino tin, n-propyl tris(diethylamino) tin, and analogous alkyl(tris)(t-butoxy) tin compounds, including sec-hexyl tris(t-butoxy) tin, t-hexyl tris(t-butoxy) tin, i-hexyl tris(t-butoxy) tin, n-hexyl tris(t-butoxy) tin, sec-pentyl tris(t-butoxy), t-pentyl tris(t-butoxy) tin, i-pentyl tris(t-butoxy) tin, n-pentyl tris(t-butoxy) tin, t-butyl tris(t-butoxy) tin, i-butyl tris(butoxy) tin, n-butyl tris(butoxy) tin, sec-butyl tris(butoxy) tin, i-propyl(tris)dimethylamino tin, or n-propyl tris(butoxy) tin. In some embodiments, the organometallic precursors or organometallic compounds are fluorinated. In some embodiments, the organometallic precursors or compounds have a boiling point less than about 200° C.

In some embodiments, the first compound or first precursor includes one or more unsaturated bonds that can be coordinated with a functional group, such as a hydroxyl group, on the surface of the substrate or an intervening underlayer to improve adhesion of the photoresist layer to the substrate or underlayer.

In some embodiments, the second precursor or second compound is at least one of an amine, a borane, a phosphine, or water. In some embodiments, the amine has a formula NₚHₙXₘ, where 0≤n≤3, 0≤m≤3, n+m=3 when p is 1, and n+m=4 when p is 2, and each X is independently a halogen selected from the group consisting of F, Cl, Br, and I. In some embodiments, the borane has a formula BₚHₙAₘ, where 0≤n≤3, 0≤m≤3, n+m=3 when p is 1, and n+m=4 when p is 2, and each X is independently a halogen selected from the group consisting of F, Cl, Br, and I. In some embodiments, the phosphine has a formula PₚHₙXₘ, where 0≤n≤3, 0≤m≤3, n+m=3, when p is 1, or n+m=4 when p is 2, and each X is independently a halogen selected from the group consisting of F, Cl, Br, and I.

FIG. 14B shows metallic precursors undergoing a reaction as a result of exposure to actinic radiation in some embodiments. As a result of exposure to the actinic radiation, ligand groups L are split off from the metallic core M⁺ of the metallic precursors, and two or more metallic precursor cores bond with each other.

FIG. 14C shows examples of organometallic precursors according to embodiments of the disclosure. In FIG. 14C, Bz is a benzene group.

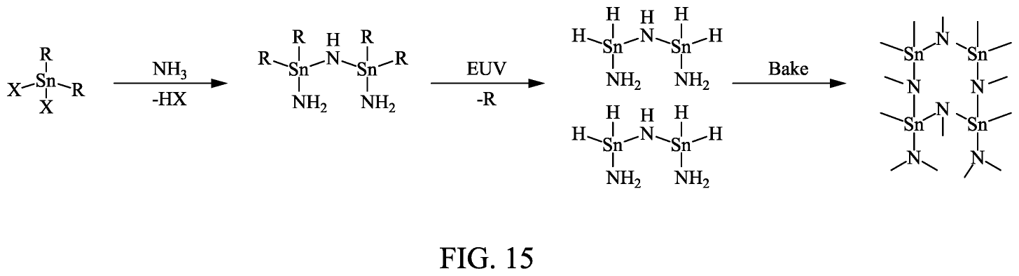

FIG. 15 shows a reaction the photoresist composition components undergo as a result of exposure to actinic radiation and heating according to an embodiment of the disclosure. FIG. 15 shows an exemplary chemical structure of the photoresist layer at various stages of the photoresist patterning method according to embodiments of the disclosure. As shown in FIG. 15, the photoresist composition includes an organometallic compound, for example SnX₂R₂, and a second compound, for example ammonia (NH₃). When the organometallic compound and the ammonia are combined, the organometallic compound reacts with some of the ammonia in the vapor phase to form a reaction product with amine groups attached to the metal (Sn) of the organometallic compound. The amine groups in the as deposited photoresist layer have hydrogen bonds that can substantially increase the boiling point of the deposited photoresist layer and help prevent the outgassing of metal-containing photoresist material. Moreover, the hydrogen bonds of the amine groups can help control the effect moisture has on photoresist layer quality.

When subsequently exposed to extreme ultraviolet radiation, the organometallic compound absorbs the extreme ultraviolet radiation and one or more organic R groups are cleaved from the organometallic compound to form an amino metallic compound in the radiation exposed areas. Then, when the post exposure bake (PEB) performed, the amino metallic compounds crosslink through the amine groups in some embodiments, as shown in FIG. 15. In some embodiments, partial crosslinking of the amino metallic compounds occurs as a result of the exposure to extreme ultraviolet radiation.

In some embodiments, the operation S110 of forming and coating a photoresist composition over a substrate is performed by a vapor phase deposition operation. In some embodiments, the vapor phase deposition operation includes atomic layer deposition (ALD) and chemical vapor deposition (CVD). In some embodiments, the ALD includes plasma-enhanced atomic layer deposition (PE-ALD); the CVD includes plasma-enhanced chemical vapor deposition (PE-CVD), metal-organic chemical vapor deposition (MO-CVD), atmospheric pressure chemical vapor deposition (AP-CVD), and low pressure chemical vapor deposition (LP-CVD).

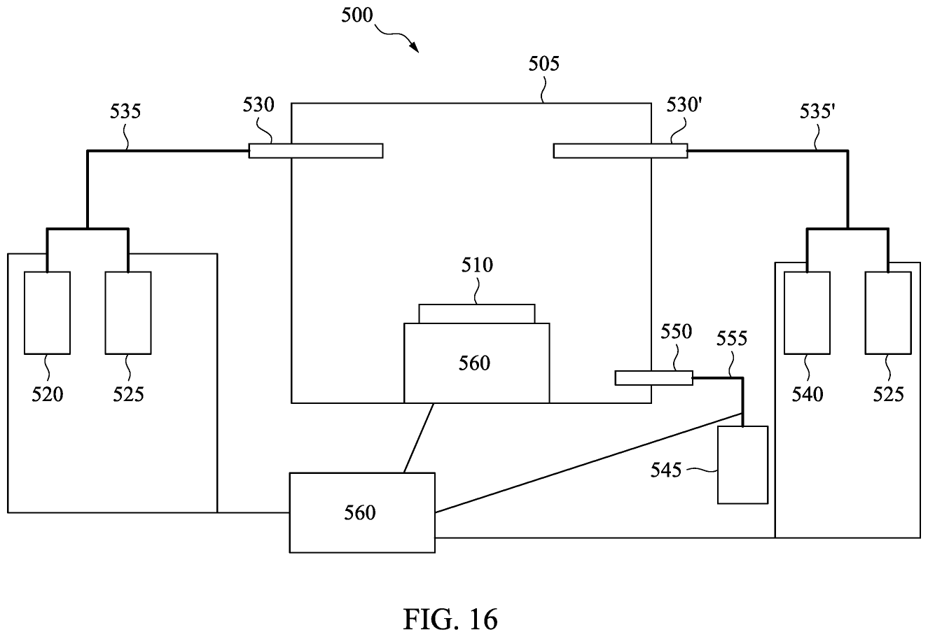

A resist layer deposition apparatus 500 according to some embodiments of the disclosure is shown in FIG. 16. In some embodiments, the deposition apparatus 500 is an ALD or CVD apparatus. The deposition apparatus 500 includes a vacuum chamber 505. A substrate support stage 570 in the vacuum chamber 505 supports a substrate 510, such as silicon wafer. In some embodiments, the substrate support stage 570 includes a heater. A first precursor or compound gas supply 520 and carrier/purge gas supply 525 are connected to an inlet 530 in the chamber via a gas line 535, and a second precursor or compound gas supply 540 and carrier/purge gas supply 525 are connected to another inlet 530′ in the chamber via another gas line 535′ in some embodiments. The chamber is evacuated, and excess reactants and reaction byproducts are removed by a vacuum pump 545 via an outlet 550 and exhaust line 555. In some embodiments, the flow rate or pulses of precursor gases and carrier/purge gases, evacuation of excess reactants and reaction byproducts, pressure inside the vacuum chamber 505, and temperature of the vacuum chamber 505 or wafer support stage 570 are controlled by a controller 560 configured to control each of these parameters.

Depositing a photoresist layer includes combining the first compound or first precursor and the second compound or second precursor in a vapor state to form the photoresist composition in some embodiments. In some embodiments, the first compound or first precursor and the second compound or second precursor of the photoresist composition are introduced into the deposition chamber 505 (CVD chamber) at about the same time via the inlets 530, 530′. In some embodiments, the first compound or first precursor and second compound or second precursor are introduced into the deposition chamber 205 (ALD chamber) in an alternating manner via the inlets 530, 530′, i.e.—first one compound or precursor then a second compound or precursor, and then subsequently alternately repeating the introduction of the one compound or precursor followed by the second compound or precursor.

In some embodiments, the deposition chamber temperature ranges from about 30° C. to about 400° C. during the deposition operation, and between about 50° C. to about 250° C. in other embodiments. In some embodiments, the pressure in the deposition chamber ranges from about 5 mTorr to about 100 Torr during the deposition operation, and between about 100 mTorr to about 10 Torr in other embodiments. In some embodiments, the plasma power is less than about 1000 W. In some embodiments, the plasma power ranges from about 100 W to about 900 W. In some embodiments, the flow rate of the first compound or precursor and the second compound or precursor ranges from about 100 sccm to about 1000 sccm. In some embodiments, the ratio of the flow of the organometallic compound precursor to the second compound or precursor ranges from about 1:1 to about 1:5. At operating parameters outside the above-recited ranges, unsatisfactory photoresist layers result in some embodiments. In some embodiments, the photoresist layer formation occurs in a single chamber (a one-pot layer formation).

In a CVD process according to some embodiments of the disclosure, two or more gas streams, in separate inlet paths 530, 535 and 530′, 535′, of an organometallic precursor and a second precursor are introduced to the deposition chamber 505 of a CVD apparatus, where they mix and react in the gas phase, to form a reaction product. The streams are introduced using separate injection inlets 230, 230′ or a dual-plenum showerhead in some embodiments. The deposition apparatus is configured so that the streams of organometallic precursor and second precursor are mixed in the chamber, allowing the organometallic precursor and second precursor to react to form a reaction product. Without limiting the mechanism, function, or utility of the disclosure, it is believed that the product from the vapor-phase reaction becomes heavier in molecular weight, and is then condensed or otherwise deposited onto the substrate 510.

In some embodiments, an ALD process is used to deposit the photoresist layer. During ALD, a layer is grown on a substrate 510 by exposing the surface of the substrate to alternate gaseous compounds (or precursors). In contrast to CVD, the precursors are introduced as a series of sequential, non-overlapping pulses. In each of these pulses, the precursor molecules react with the surface in a self-limiting way, so that the reaction terminates once all the reactive sites on the surface are consumed. Consequently, the maximum amount of material deposited on the surface after a single exposure to all of the precursors (a so-called ALD cycle) is determined by the nature of the precursor-surface interaction.

In an embodiment of an ALD process, an organometallic precursor is pulsed to deliver the metal-containing precursor to the substrate 510 surface in a first half reaction. In some embodiments, the organometallic precursor reacts with a suitable underlying species (for example OH or NH functionality on the surface of the substrate) to form a new self-saturating surface. Excess unused reactants and the reaction by-products are removed, by an evacuation-pump down using a vacuum pump 545 and/or by a flowing an inert purge gas in some embodiments. Then, a second precursor, such as ammonia (NH₃), is pulsed to the deposition chamber in some embodiments. The NH₃ reacts with the organometallic precursor on the substrate to obtain a reaction product photoresist on the substrate surface. The second precursor also forms self-saturating bonds with the underlying reactive species to provide another self-limiting and saturating second half reaction. A second purge is performed to remove unused reactants and the reaction by-products in some embodiments. Pulses of the first precursor and second precursor are alternated with intervening purge operations until a desired thickness of the photoresist layer is achieved.

In some embodiments, the photoresist layer 15 is formed to a thickness of about 5 nm to about 50 nm, and to a thickness of about 10 nm to about 30 nm in other embodiments. A person of ordinary skill in the art will recognize that additional ranges of thicknesses within the explicit ranges above are contemplated and are within the present disclosure. The thickness can be evaluated using non-contact methods of x-ray reflectivity and/or ellipsometry based on the optical properties of the photoresist layers. In some embodiments, each photoresist layer thickness is relatively uniform to facilitate processing. In some embodiments, the variation in thickness of the deposited photoresist layer varies by no more than ±25% from the average thickness, in other embodiments each photoresist layer thickness varies by no more than ±10% from the average photoresist layer thickness. In some embodiments, such as high uniformity depositions on larger substrates, the evaluation of the photoresist layer uniformity may be evaluated with a 1 centimeter edge exclusion, i.e., the layer uniformity is not evaluated for portions of the coating within 1 centimeter of the edge. A person of ordinary skill in the art will recognize that additional ranges within the explicit ranges above are contemplated and are within the present disclosure.

In some embodiments, the first and second compounds or precursors are delivered into the deposition chamber 505 with a carrier gas. The carrier gas, a purge gas, a deposition gas, or other process gas may contain nitrogen, hydrogen, argon, neon, helium, or combinations thereof.

In some embodiments, the organometallic compound includes tin (Sn), antimony (Sb), bismuth (Bi), indium (In), and/or tellurium (Te) as the metal component, however, the disclosure is not limited to these metals. In other embodiments, additional suitable metals include titanium (Ti), zirconium (Zr), hafnium (Hf), vanadium (V), cobalt (Co), molybdenum (Mo), tungsten (W), aluminum (Al), gallium (Ga), silicon (Si), germanium (Ge), phosphorus (P), arsenic (As), yttrium (Y), lanthanum (La), cerium (Ce), lutetium (Lu), or combinations thereof. The additional metals can be as alternatives to or in addition to the Sn, Sb, Bi, In, and/or Te.

The particular metal used may significantly influence the absorption of radiation. Therefore, the metal component can be selected based on the desired radiation and absorption cross section. Tin, antimony, bismuth, tellurium, and indium provide strong absorption of extreme ultraviolet light at 13.5 nm. Hafnium provides good absorption of electron beam and extreme UV radiation. Metal compositions including titanium, vanadium, molybdenum, or tungsten have strong absorption at longer wavelengths, to provide, for example, sensitivity to 248 nm wavelength ultraviolet light.

In some embodiments, the resist layer 15 is formed by mixing the organometallic compound in a solvent to form a resist composition and dispensing the resist composition onto the substrate 10. To aid in the mixing and dispensing of the photoresist, the solvent is chosen at least in part based upon the materials chosen for the metallic resist. In some embodiments, the solvent is chosen such that the organometallic is evenly dissolved into the solvent and dispensed upon the layer to be patterned.

In some embodiments, the photoresist exposure radiation is extreme ultraviolet radiation produced by a CO₂ laser-excited Sn plasma (wavelength of 13.5 nm). In other embodiments, ultraviolet radiation, including g-line (wavelength of about 436 nm), i-line (wavelength of about 365 nm), far ultraviolet radiation, or electron beams are used to selectively expose the photoresist layer. In some embodiments, the radiation source is selected from the group consisting of a mercury vapor lamp, xenon lamp, carbon arc lamp, a KrF excimer laser light (wavelength of 248 nm), an ArF excimer laser light (wavelength of 193 nm), an F₂ excimer laser light (wavelength of 157 nm), in addition to the CO₂ laser-excited Sn plasma.

In some embodiments, the exposure of the photoresist layer 15 uses an immersion lithography technique. In such a technique, an immersion medium (not shown) is placed between the final optics and the photoresist layer, and the exposure radiation 45 passes through the immersion medium.

In some embodiments, the photoresist developer 57 includes a solvent, and an acid or a base. In some embodiments, the developer includes one or more solvents selected from group consisting of n-butyl acetate, methyl n-amyl ketone, hexane, heptane, amyl acetate, ethylene glycol, propylene glycol methyl ether, propylene glycol ethyl ether, γ-butyrolactone, cyclohexanone, ethyl lactate, methanol, ethanol, propanol, n-butanol, acetone, dimethyl formamide, acetonitrile, isopropanol, and tetrahydrofuran. In some embodiments, the acid is one or more of acetic acid, ethanedioic acid, methanoic acid, 2-hydroxypropanoic acid, 2-hydroxybutanedioic acid, citric acid, uric acid, trifluoromethanesulfonic acid, benzenesulfonic acid, ethanesulfonic acid, methanesulfonic acid, and maleic acid. In some embodiments, suitable bases for the photoresist developer composition 57 include an alkanolamine, a triazole, or an ammonium compound. In some embodiments, suitable bases include an organic base selected from the group consisting of monoethanolamine, monoisopropanolamine, 2-amino-2-methyl-1-propanol, 1H-benzotriazole, 1,2,4-triazole, 1,8-diazabicycloundec-7-ene, tetramethylammonium hydroxide, tetraethylammonium hydroxide, tetrapropylammonium hydroxide, and tetrabutylammonium hydroxide, and combinations thereof; or inorganic bases selected from the group consisting of ammonium hydroxide, ammonium sulfamate, ammonium carbamate, and combinations thereof or inorganic bases selected from the group consisting of ammonium hydroxide, ammonium sulfamate, ammonium carbamate, and combinations thereof. In some embodiments, the base is selected from the group consisting of monoisopropanolamine, 2-amino-2-methyl-1-propanol, 1H-benzotriazole, 1,2,4-triazole, 1,8-diazabicycloundec-7-ene, and combinations thereof. In some embodiments, the developer further includes water.

In some embodiments, the developer 57 is applied to the photoresist layer 15 using a spin-on process. In the spin-on process, the developer 57 is applied to the photoresist layer 15 from above the photoresist layer 15 while the photoresist coated substrate is rotated, as shown in FIG. 11. In some embodiments, the developer 57 is supplied at a rate of between about 5 ml/min and about 800 ml/min, while the photoresist coated substrate 10 is rotated at a speed of between about 100 rpm and about 2000 rpm. In some embodiments, the developer is at a temperature of between about 10° C. and about 80° C. The development operation continues for between about 30 seconds to about 10 minutes in some embodiments. In some embodiments, a plasma development operation is performed.

While the spin-on operation is one suitable method for developing the photoresist layer 15 after exposure, it is intended to be illustrative and is not intended to limit the embodiment. Rather, any suitable development operations, including dip processes, puddle processes, and spray-on methods, may alternatively be used. All such development operations are included within the scope of the embodiments.

During the development process, the developer 57 dissolves the radiation-unexposed regions 52 of negative-tone resists to form a pattern 55a, exposing the surface of the substrate 10, as shown in FIG. 12, leaving behind well-defined exposed photoresist regions 50, having improved definition than provided by conventional negative photoresist photolithography.

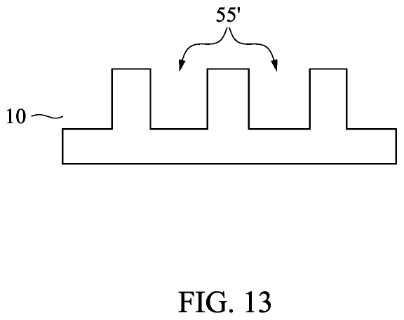

After the developing operation S150, remaining developer is removed from the patterned photoresist covered substrate. The remaining developer is removed using a spin-dry process in some embodiments, although any suitable removal technique may be used. After the photoresist layer 15 is developed, and the remaining developer is removed, additional processing is performed while the patterned photoresist layer 50, 52 is in place. For example, an etching operation, using dry or wet etching, is performed in some embodiments, to transfer the pattern 55 of the photoresist layer to the underlying substrate 10, forming recesses 55′, as shown in FIG. 13. The substrate 10 has a different etch resistance than the photoresist layer 15. In some embodiments, the etchant is more selective to the substrate 10 than the photoresist layer 15.

In some embodiments, the substrate 10 and the photoresist layer 15 contain at least one etching resistance molecule. In some embodiments, the etching resistant molecule includes a molecule having a low Onishi number structure, a double bond, a triple bond, silicon, silicon nitride, titanium, titanium nitride, aluminum, aluminum oxide, silicon oxynitride, combinations thereof, or the like.

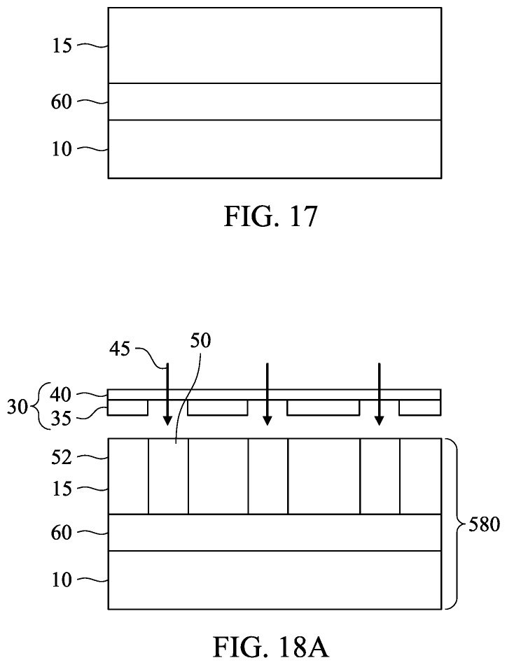

In some embodiments, a layer to be patterned 60 is disposed over the substrate prior to forming the photoresist layer, as shown in FIG. 17. In some embodiments, the layer to be patterned 60 is a metallization layer or a dielectric layer, such as a passivation layer, disposed over a metallization layer. In embodiments where the layer to be patterned 60 is a metallization layer, the layer to be patterned 60 is formed of a conductive material using metallization processes, and metal deposition techniques, including chemical vapor deposition, atomic layer deposition, and physical vapor deposition (sputtering). Likewise, if the layer to be patterned 60 is a dielectric layer, the layer to be patterned 60 is formed by dielectric layer formation techniques, including thermal oxidation, chemical vapor deposition, atomic layer deposition, and physical vapor deposition.

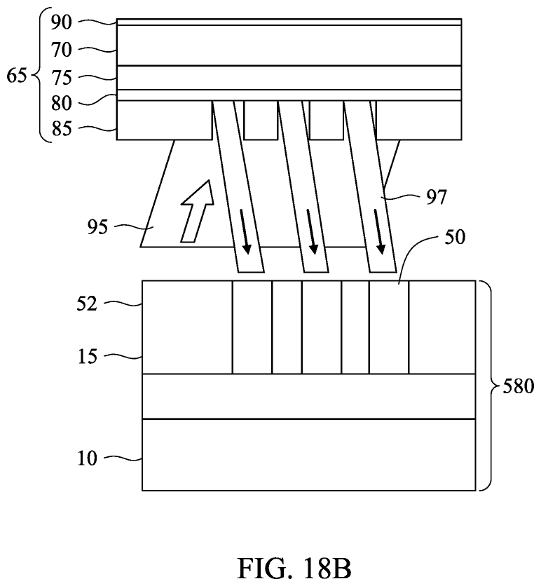

The photoresist layer 15 is subsequently selectively exposed to actinic radiation to form exposed regions 50 and unexposed regions 52 in the photoresist layer, as shown in FIGS. 18A and 18B, and described herein in relation to FIGS. 3A and 3B.

The exposed photoresist coated substrate 580 is subsequently heated as described in relation to FIGS. 4A-10B.

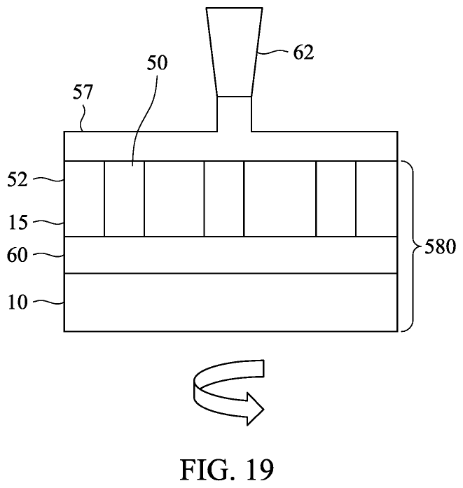

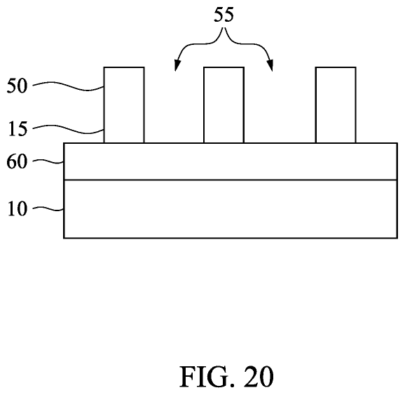

As shown in FIG. 19, the photoresist layer 15 is developed by dispensing developer 57 from a dispenser 62 to form a pattern of photoresist openings 55, as shown in FIG. The development operation is similar to that explained with reference to FIGS. 11, herein. In some embodiments, where the photoresist is a negative-tone resist, the unexposed portion of the photoresist layer 52 is removed by the developer 57 forming a pattern of openings 55 in the photoresist layer 15 to expose the layer to be patterned 60, as shown in FIG. 20.

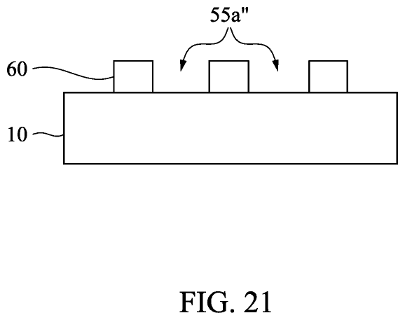

Then as shown in FIG. 21, the pattern 55 in the photoresist layer 15 is transferred to the layer to be patterned 60 using an etching operation and the photoresist layer is removed, as explained with reference to FIG. 13 to form the pattern 55″ in the layer to be patterned 60.

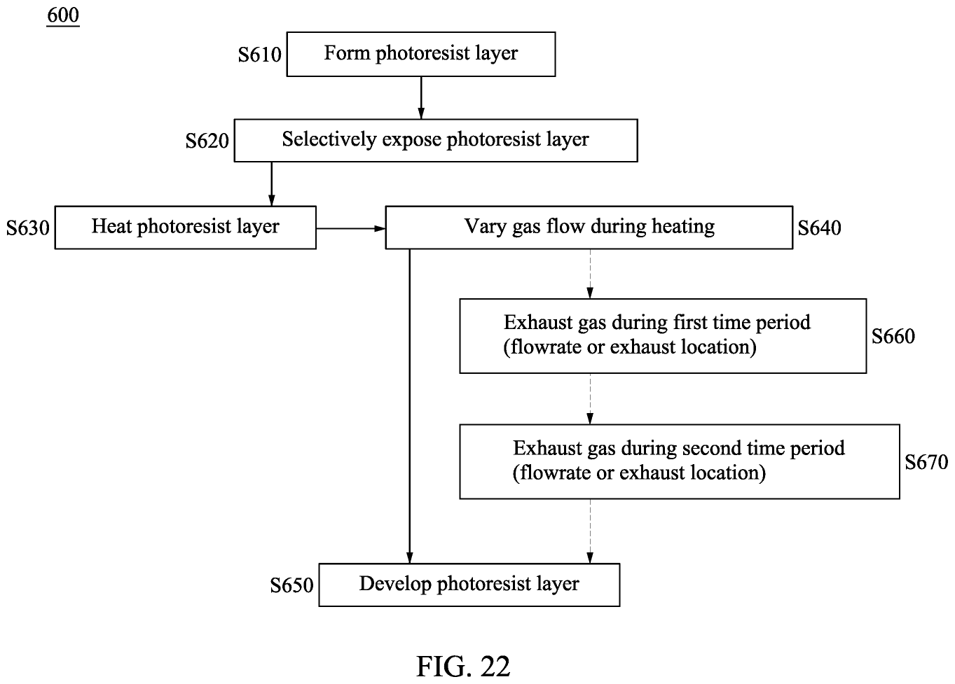

A method 600 of manufacturing a semiconductor device is illustrated in FIG. 22. A photoresist layer 15 is formed over a substrate 10 in operation S610. The photoresist layer 15 is selectively exposed to actinic radiation in operation S620. Then, in operation S630, the photoresist layer 15 is heated after selectively exposing the photoresist layer to actinic radiation. During the heating, the photoresist layer 15 a gas is flowed over the photoresist layer in operation S640. While the gas is flowing over the photoresist layer, the flow is varied in operation S640. In operation S650, the photoresist layer 15 is developed after the heating to form a pattern 55 in the photoresist layer. In some embodiments, the gas is supplied to a space over the photoresist layer 15 through a gas manifold 220, and the gas manifold has a one or more gas exhausts located at an edge portion of the manifold or a central portion of the manifold 220. During a first time period the gas is exhausted at a first flowrate and through the gas exhausts in the central portion or edge portion the manifold 220 in operation S660. Then in operation S670, during a second time period the gas is exhausted at a second different flowrate or through a different gas exhausts than in the operation S660.

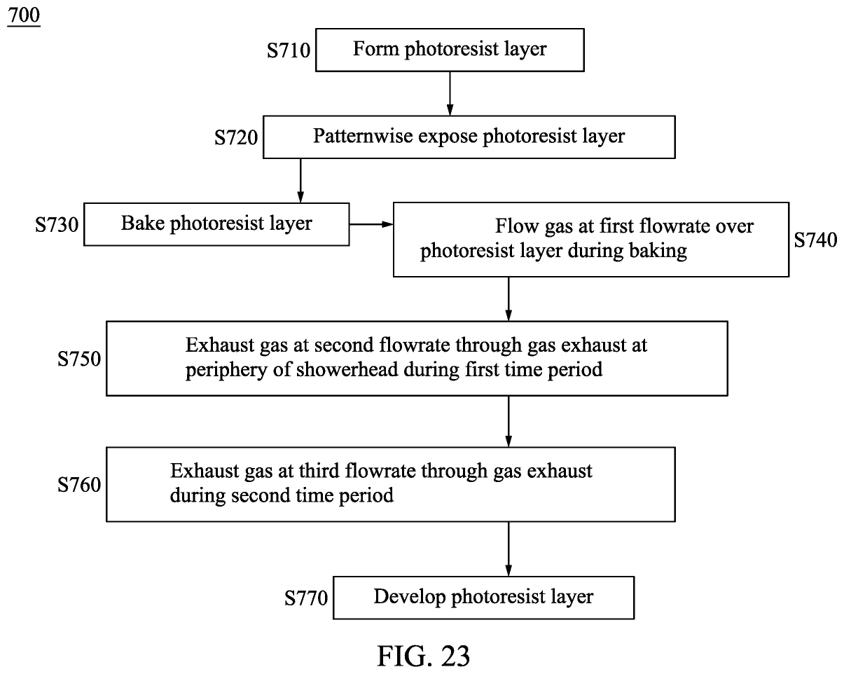

Another method 700 of manufacturing a semiconductor device is illustrated in the flowchart of FIG. 23. A photoresist layer 15 is formed over a substrate 10 in operation S710. The photoresist layer 15 is patternwise (or selectively) exposed to actinic radiation in operation S720. Then, in operation S730, the photoresist layer 15 is baked after patternwise exposing the photoresist layer to actinic radiation. During the baking the photoresist layer 15, a gas is flowed over the photoresist layer at a first flowrate in operation S740. In operation S750, the gas is exhausted at a second flowrate through one or more gas exhausts 290a at a periphery of a showerhead during a first time period. Then, the gas is exhausted through the one or more gas exhausts 290a at the periphery of the showerhead at a third flowrate during a second time period, wherein the third flowrate is greater than the second flowrate in operation S760. The photoresist layer 15 is subsequently developed after the heating to form a pattern 55 in the photoresist layer in operation S770.

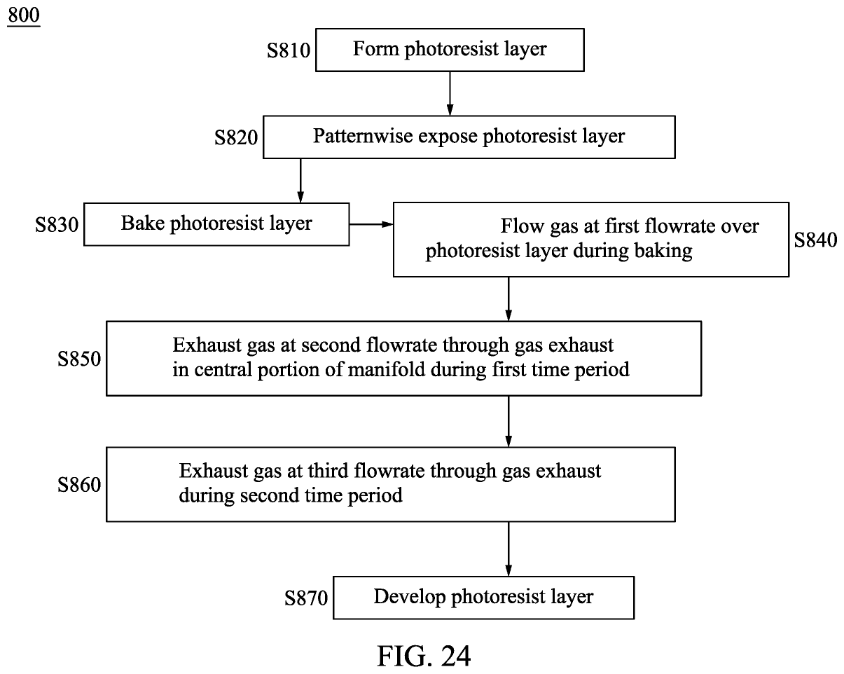

Another method 800 of manufacturing a semiconductor device is illustrated in the flowchart of FIG. 24. A photoresist layer 15 is formed over a substrate 10 in operation S810. The photoresist layer 15 is patternwise (or selectively) exposed to actinic radiation in operation S820. Then, in operation S830, the photoresist layer 15 is baked after patternwise exposing the photoresist layer to actinic radiation. During the baking the photoresist layer 15, a gas is flowed over the photoresist layer at a first flowrate in operation S840. In operation S850, the gas is exhausted at a second flowrate through a gas exhaust in a central portion of a manifold during a first time period. Then, the gas is exhausted through the gas exhaust in the central portion of the manifold 220 at a third flowrate during a second time period, wherein the third flowrate is greater than the second flowrate in operation S860. The photoresist layer 15 is subsequently developed after the heating to form a pattern 55 in the photoresist layer in operation S770.

Other embodiments include other operations before, during, or after the operations described above. In some embodiments, the disclosed methods include forming fin field effect transistor (FinFET) structures. In some embodiments, a plurality of active fins are formed on the semiconductor substrate. Such embodiments, further include etching the substrate through the openings of a patterned hard mask to form trenches in the substrate; filling the trenches with a dielectric material; performing a chemical mechanical polishing (CMP) process to form shallow trench isolation (STI) features; and epitaxy growing or recessing the STI features to form fin-like active regions. In some embodiments, one or more gate electrodes are formed on the substrate. Some embodiments include forming gate spacers, doped source/drain regions, contacts for gate/source/drain features, etc. In other embodiments, a target pattern is formed as metal lines in a multilayer interconnection structure. For example, the metal lines may be formed in an inter-layer dielectric (ILD) layer of the substrate, which has been etched to form a plurality of trenches. The trenches may be filled with a conductive material, such as a metal; and the conductive material may be polished using a process such as chemical mechanical planarization (CMP) to expose the patterned ILD layer, thereby forming the metal lines in the ILD layer. The above are non-limiting examples of devices/structures that can be made and/or improved using the method described herein.

In some embodiments, active components such diodes, field-effect transistors (FETs), FinFETs, gate all around field effect transistors (GAA FETs), metal-oxide semiconductor field effect transistors (MOSFET), complementary metal-oxide semiconductor (CMOS) transistors, bipolar transistors, high voltage transistors, high frequency transistors, other three-dimensional (3D) FETs, other memory cells, and combinations thereof are formed, according to embodiments of the disclosure.

In embodiments of the disclosure, actinic radiation exposure dose reduction is achieved by a using a sequential post exposure bake (PEB) process. Exposure dose reduction is achieved by using an initial longer time, lower flowrate exhaust during the PEB followed by a shorter time, higher flowrate exhaust. Exposure dose reduction is be achieved by the lower flowrate exhaust, and chamber contamination is mitigated by the shorter time, higher flowrate exhaust in some embodiments. The lower flowrate exhaust is used to keep more reactants remaining within the photoresist film during most of the post exposure baking process to enhance the crosslinking reaction. As a result, exposure dose and the cost of operation (CoO) for methods according to embodiments of the disclosure are significantly reduced.

In some embodiments of the disclosure, up to a 10% reduction in exposure dose is achieved with about the same line width roughness (LWR) and critical dimension (CD) range as patterns formed using a similar photolithography method without the sequential PEB exhaust process of the present disclosure when forming patterns with a 30 nm pitch. In some embodiments of the disclosure, up to about a 7% improvement in critical dimension in the photoresist pattern is achieved, as shown by after development inspection, compared to patterns formed by a similar photolithographic process not using the sequential PEB exhaust techniques of the present disclosure. In addition, wafer bevel and wafer backside contamination levels are about the same as similar photolithographic not using the sequential PEB exhaust techniques of the present disclosure, as determined by chamber Sn Ion Chromatography (ICP).

An embodiment of the disclosure is a method of manufacturing a semiconductor device, including forming a photoresist layer comprising a photoresist composition over a substrate. The photoresist layer is selectively exposed to actinic radiation. The photoresist layer is heated after selectively exposing the photoresist layer to actinic radiation. A gas is flowed over the photoresist layer during the heating the photoresist layer. A flow of the gas is varied during the heating the photoresist layer. The photoresist layer is developed after the heating the photoresist layer to form a pattern in the photoresist layer. In an embodiment, during the heating, the photoresist layer is heated at a temperature ranging from 70° C. to 220° C. In an embodiment, during the heating, the photoresist layer is heated at a temperature ranging from 150° C. to 190° C. In an embodiment, during the heating, the photoresist layer is heated for 40 seconds to 200 seconds. In an embodiment, during the heating, the photoresist layer is heated for 65 seconds to 175 seconds. In an embodiment, during the flowing a gas over the photoresist layer, the gas is supplied to a space over the photoresist layer and exhausted from the space through a manifold. In an embodiment, the manifold includes a plurality of gas supply openings and one or more of gas exhausts. In an embodiment, the plurality of gas supply openings are arranged across a face of the manifold in a showerhead configuration. In an embodiment, the one or more gas exhausts are located at a central portion of the manifold or an edge portion of the manifold. In an embodiment, the gas is exhausted from only gas exhausts located at the edge portion of the manifold during a first time period of the flowing a gas over the photoresist layer, and then the gas is exhausted from the gas exhausts located at the edge portion and a gas exhaust located at the central portion of the manifold during a second time period of the flowing a gas over the photoresist layer. In an embodiment, the first time period is longer than the second time period. In an embodiment, the first time period ranges from 40 seconds to 200 seconds, and the second time period ranges from 2 seconds to 85 seconds. In an embodiment, the first time period ranges from 60 seconds to 115 seconds, and the second time period ranges from 5 seconds to 60 seconds. In an embodiment, a flowrate of the gas supplied to the space ranges from 1 L/min to 20 L/min, a flowrate of the gas through the gas exhausts located at the edge portion of the manifold ranges from 1 L/min to 20 L/min during the first time period and the second time period, and a flowrate of the gas through the gas exhaust located at the central portion of the manifold ranges from 10 L/min to 80 L/min during the second time period. In an embodiment, a flowrate of the gas supplied to the space ranges from 2 L/min to 10 L/min, a flowrate of the gas through the gas exhausts located at the edge portion of the manifold ranges from 2 L/min to 10 L/min during the first time period and the second time period, and a flowrate of the gas through the gas exhaust located at the central portion of the manifold ranges from 20 L/min to 60 L/min during the second time period. In an embodiment, the flowrate of the gas through the gas exhaust located at the central portion of the manifold during the second time period is greater than the flowrate of the gas through the gas exhausts located at the edge portion of the manifold. In an embodiment, the flowrate of the gas through the gas exhaust located at the central portion of the manifold during the second time period is greater than the flowrate of the gas supplied through the manifold. In an embodiment, the one or more gas exhausts are located at an edge portion of the manifold. In an embodiment, the gas is exhausted from the one or more gas exhausts at a first flowrate during a first time period of the flowing a gas over the photoresist layer, and then the gas is exhausted from the one or more gas exhausts at a second flowrate during a second time period of the flowing a gas over the photoresist layer, wherein the second flowrate is greater than the first flowrate. In an embodiment, the first time period is longer than the second time period. In an embodiment, the first time period ranges from 40 seconds to 200 seconds, and the second time period ranges from 2 seconds to 85 seconds. In an embodiment, the first time period ranges from 60 seconds to 115 seconds, and the second time period ranges from 5 seconds to 60 seconds. In an embodiment, a flowrate of the gas supplied to the space ranges from 1 L/min to 20 L/min, and a flowrate of the gas through the gas exhausts located at the edge portion of the manifold ranges from 1 L/min to 20 L/min during the first time period and ranges from 10 L/min to 80 L/min during the second time period. In an embodiment, a flowrate of the gas supplied to the space ranges from 2 L/min to 10 L/min, a flowrate of the gas through the gas exhausts located at the edge portion of the manifold ranges from 2 L/min to 10 L/min during the first time period and ranges from 20 L/min to 60 L/min during the second time period. In an embodiment, an exhaust flowrate of the gas through the gas exhausts located at the edge portion of the manifold during the second time period is greater than the flowrate of the gas supplied to the space. In an embodiment, the gas outlet is located at a central portion of the manifold. In an embodiment, the gas is exhausted from the gas exhaust at a first flowrate during a first time period of the flowing a gas over the photoresist layer, and then the gas is exhausted from the gas exhaust at a second flowrate during a second time period of the flowing a gas over the photoresist layer, wherein the second flowrate is greater than the first flowrate. In an embodiment, the first time period is longer than the second time period. In an embodiment, the first time period ranges from 40 seconds to 200 seconds, and the second time period ranges from 2 seconds to 85 seconds. In an embodiment, the first time period ranges from 60 seconds to 115 seconds, and the second time period ranges from 5 seconds to 60 seconds. In an embodiment, a flowrate of the gas supplied to the space ranges from 1 L/min to 20 L/min, and an exhaust flowrate through the gas exhaust ranges from 1 L/min to 20 L/min during the first time period and ranges from 10 L/min to 80 L/min during the second time period. In an embodiment, a flowrate of the gas supplied to the space ranges from 2 L/min to 10 L/min, an exhaust flowrate through the gas exhaust ranges from 2 L/min to 10 L/min during the first time period and ranges from 20 L/min to 60 L/min during the second time period. In an embodiment, a flowrate of the gas through the gas exhausts located at the edge portion of the manifold during the second time period is greater than the flowrate of the gas supplied through the gas inlets. In an embodiment, the photoresist composition includes an organometallic compound.

Another embodiment of the disclosure is a method of manufacturing a semiconductor device, including forming a photoresist layer comprising a photoresist composition over a substrate. The photoresist layer is patternwise exposed to actinic radiation. The photoresist layer is baked after the patternwise exposing the photoresist layer to actinic radiation. A gas is flowed over the photoresist layer during the baking the photoresist layer. During the flowing a gas over the photoresist layer, the gas is supplied to a space over the photoresist layer at a first flowrate from a gas showerhead located over a main surface of the photoresist layer, and the gas is exhausted from the space over the photoresist layer through one or more gas exhausts located adjacent a periphery of the showerhead. The gas is exhausted from the space over the photoresist layer at a second flowrate for a first time period and then exhausted at a third flowrate for a second time period. The third flowrate is greater than the second flowrate. The photoresist layer is developed after the baking the photoresist layer to form a pattern in the photoresist layer. In an embodiment, a ratio of the third flowrate to the second flowrate ranges from greater than 1 to 80. In an embodiment, a ratio of the third flowrate to the second flowrate ranges from 2 to 30. In an embodiment, a ratio of the first flowrate to the second flowrate ranges from 0.2 to 5. In an embodiment, the first flowrate and the second flowrate are equal. In an embodiment, a ratio of the second time period to the first time period ranges from 0.01 to less than 1. In an embodiment, a ratio of the second time period to the first time period ranges from 0.04 to 0.5. In an embodiment, during the baking, the photoresist layer is heated at a temperature ranging from 70° C. to 220° C.

Another embodiment of the disclosure is a method of manufacturing a semiconductor device, including forming a photoresist layer including a photoresist composition over a substrate. The photoresist layer is patternwise exposed to actinic radiation. The photoresist layer is baked after patternwise exposing the photoresist layer to actinic radiation. A gas is flowed in a space over the photoresist layer during the baking the photoresist layer. During the flowing a gas over the photoresist layer, the gas is supplied to the space over the photoresist layer at a first flowrate from a plurality of first openings in a manifold located over a main surface of the photoresist layer, and the gas is exhausted from the space over the photoresist layer through a second opening located in a central portion of the manifold. The gas is exhausted from the space over the photoresist layer at a second flowrate for a first time period and then exhausted at a third flowrate for a second time period. The third flowrate is greater than the second flowrate. The photoresist layer is developed after baking the photoresist layer to form a pattern in the photoresist layer. In an embodiment, a ratio of the third flowrate to the second flowrate ranges from greater than 1 to 80. In an embodiment, a ratio of the third flowrate to the second flowrate ranges from 2 to 30. In an embodiment, a ratio of the first flowrate to the second flowrate ranges from 0.2 to 5. In an embodiment, the first flowrate and the second flowrate are equal. In an embodiment, a ratio of the second time period to the first time period ranges from 0.01 to less than 1. In an embodiment, a ratio of the second time period to the first time period ranges from 0.04 to 0.5. In an embodiment, during the baking, the photoresist layer is heated at a temperature ranging from 70° C. to 220° C.

Another embodiment of the disclosure is a semiconductor device manufacturing tool, including a processing chamber and a wafer support disposed inside the processing chamber. A heating element is disposed inside the wafer support and a gas manifold disposed over the wafer support. The gas manifold includes a plurality of first openings in a surface of the gas manifold facing the wafer support configured to direct a gas flowing through the first openings towards the wafer support, and one or more second openings configured to exhaust the gas away from wafer support. The one or more second openings are located in a peripheral portion of the gas manifold or in a central portion of the gas manifold. A controller is configured to control: a flowrate of the gas flowing through the first openings, a flowrate of the gas flowing through the one or more second openings; and a temperature of the heating element. In an embodiment, the semiconductor device manufacturing tool includes a source of the gas. In an embodiment, the semiconductor device manufacturing tool includes a first vacuum pump communicating with the processing chamber. In an embodiment, the semiconductor device manufacturing tool includes a second vacuum pump communicating with the one or more second openings. In an embodiment, the controller is configured to control a flow of the gas flowing through the second openings so that the gas flows through only second openings located in the peripheral portion of the gas manifold during a first time period of exhausting the gas away from wafer support, and then the gas flows through the gas exhausts located in the peripheral portion and a gas exhaust located in the central portion of the manifold during a second time period. In an embodiment, the first time period is controlled to be longer than the second time period. In an embodiment, the flowrate of the gas flowing through the first openings ranges from 1 L/min to 20 L/min, the flowrate of the gas flowing through the second openings located in the peripheral portion of the manifold ranges from 1 L/min to 20 L/min during the first time period and the second time period, and the flowrate of the gas flowing through the second opening located in the central portion of the manifold ranges from 10 L/min to 80 L/min during the second time period. In an embodiment, the flowrate of the gas flowing through the second opening located in the central portion of the manifold during the second time period is greater than the flowrate of the gas flowing through the second openings located in the peripheral portion of the manifold. In an embodiment, the flowrate of the gas flowing through the second opening located at the central portion of the manifold during the second time period is greater than the flowrate of the gas flowing through the first openings.

Another embodiment of the disclosure is a semiconductor device manufacturing tool, including a chamber and a hot plate disposed inside the chamber. A gas showerhead is disposed over the hot plate. One or more gas exhausts is disposed adjacent an edge of the gas showerhead. A controller configured to control a first flowrate of a gas flowing through the showerhead towards the hot plate, a second and a third flowrate of the gas flowing through the one or more gas exhausts after the gas flows through the showerhead, and a temperature of the hot plate. The gas flows through the one or more exhausts at the second flowrate for a first time period and then flows at a third flowrate for a second time period. The third flowrate is greater than the second flowrate. In an embodiment, the semiconductor device manufacturing tool includes a source of the gas. In an embodiment, the semiconductor device manufacturing tool includes a vacuum pump communicating with the one or more gas exhausts. In an embodiment, a ratio of the third flowrate to the second flowrate ranges from greater than 1 to 80. In an embodiment, a ratio of the first flowrate to the second flowrate ranges from 0.2 to 5. In an embodiment, a ratio of the second time period to the first time period ranges from 0.01 to less than 1.

Another embodiment of the disclosure is an apparatus, including a chamber and a hot plate disposed inside the chamber. A gas manifold is disposed over the hot plate. The gas manifold includes a plurality of first openings in a surface of the manifold facing the hot plate configured to direct a gas flowing through the first openings towards the hot plate, and a second opening in a central portion configured to exhaust the gas away from the hot plate. A controller is configured to control a first flowrate of the gas flowing through the first opening towards the hot plate, a second and a third flowrate of the gas exhausted away from the hot plate after the gas flows toward the hot plate, and a temperature of the hot plate. The gas is exhausted away from the hot plate at the second flowrate for a first time period and then exhausted away from the hot plate at the third flowrate for a second time period. The third flowrate is greater than the second flowrate. In an embodiment, the apparatus includes a vacuum pump communicating with the second opening. In an embodiment, a ratio of the third flowrate to the second flowrate ranges from greater than 1 to 80. In an embodiment, a ratio of the first flowrate to the second flowrate ranges from 0.2 to 5. In an embodiment, a ratio of the second time period to the first time period ranges from 0.01 to less than 1.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a photoresist layer comprising a photoresist composition over a substrate;
selectively exposing the photoresist layer to actinic radiation;
heating the photoresist layer after selectively exposing the photoresist layer to actinic radiation,
flowing a gas over the photoresist layer during the heating the photoresist layer,
wherein a flow of the gas is varied during the heating the photoresist layer; and
developing the photoresist layer after the heating the photoresist layer to form a pattern in the photoresist layer.

2. The method according to claim 1, wherein during the heating, the photoresist layer is heated at a temperature ranging from 70° C. to 220° C.

3. The method according to claim 1, wherein during the heating, the photoresist layer is heated for 40 seconds to 200 seconds.

4. The method according to claim 1, wherein during the flowing a gas over the photoresist layer, the gas is supplied to a space over the photoresist layer and exhausted from the space through a manifold comprising a plurality of gas supply openings and one or more of gas exhausts.

5. The method according to claim 4, wherein the one or more gas exhausts are located at a central portion of the manifold or an edge portion of the manifold.

6. The method according to claim 5, wherein the gas is exhausted from only gas exhausts located at the edge portion of the manifold during a first time period of the flowing a gas over the photoresist layer, and then the gas is exhausted from the gas exhausts located at the edge portion and a gas exhaust located at the central portion of the manifold during a second time period of the flowing a gas over the photoresist layer.

7. The method according to claim 6, wherein the first time period is longer than the second time period.

8. The method according to claim 6, wherein the first time period ranges from 40 seconds to 200 seconds, and the second time period ranges from 2 seconds to 85 seconds.

9. The method according to claim 6, wherein:
a flowrate of the gas supplied to the space ranges from 1 L/min to 20 L/min,
a flowrate of the gas through the gas exhausts located at the edge portion of the manifold ranges from 1 L/min to 20 L/min during the first time period and the second time period, and
a flowrate of the gas through the gas exhaust located at the central portion of the manifold ranges from 10 L/min to 80 L/min during the second time period.

10. The method according to claim 4, wherein the one or more gas exhausts are located at an edge portion of the manifold.

11. The method according to claim 10, wherein the gas is exhausted from the one or more gas exhausts at a first flowrate during a first time period of the flowing a gas over the photoresist layer, and then the gas is exhausted from the one or more gas exhausts at a second flowrate during a second time period of the flowing a gas over the photoresist layer,
wherein the second flowrate is greater than the first flowrate.

12. The method according to claim 4, wherein the gas outlet is located at a central portion of the manifold.

13. The method according to claim 12, wherein the gas is exhausted from the gas exhaust at a first flowrate during a first time period of the flowing a gas over the photoresist layer, and then the gas is exhausted from the gas exhaust at a second flowrate during a second time period of the flowing a gas over the photoresist layer,
wherein the second flowrate is greater than the first flowrate.

14. A method of manufacturing a semiconductor device, comprising:
forming a photoresist layer comprising a photoresist composition over a substrate;
patternwise exposing the photoresist layer to actinic radiation;
baking the photoresist layer after patternwise exposing the photoresist layer to actinic radiation,
flowing a gas over the photoresist layer during the baking the photoresist layer,
wherein during the flowing a gas over the photoresist layer, the gas is supplied to a space over the photoresist layer at a first flowrate from a gas showerhead located over a main surface of the photoresist layer, and
the gas is exhausted from the space over the photoresist layer through one or more gas exhausts located adjacent a periphery of the showerhead,
wherein the gas is exhausted from the space over the photoresist layer at a second flowrate for a first time period and then exhausted at a third flowrate for a second time period,
wherein the third flowrate is greater than the second flowrate; and
developing the photoresist layer after the baking the photoresist layer to form a pattern in the photoresist layer.

15. The method according to claim 14, wherein a ratio of the third flowrate to the second flowrate ranges from greater than 1 to 80.

16. The method according to claim 14, wherein a ratio of the first flowrate to the second flowrate ranges from 0.2 to 5.

17. The method according to claim 14, wherein a ratio of the second time period to the first time period ranges from 0.01 to less than 1.

18. A semiconductor device manufacturing tool, comprising:
a processing chamber;
a wafer support disposed inside the processing chamber;
a heating element disposed inside the wafer support;
a gas manifold disposed over the wafer support,
wherein the gas manifold comprises:
a plurality of first openings in a surface of the gas manifold facing the wafer support configured to direct a gas flowing through the first openings towards the wafer support, and
one or more second openings configured to exhaust the gas away from wafer support,
wherein the one or more second openings are located in a peripheral portion of the gas manifold or in a central portion of the gas manifold; and
a controller configured to control:
a flowrate of the gas flowing through the first openings;
a flowrate of the gas flowing through the one or more second openings; and
a temperature of the heating element.

19. The semiconductor device manufacturing tool of claim 18, wherein the controller is configured to control a flow of the gas flowing through the second openings so that the gas flows through only second openings located in the peripheral portion of the gas manifold during a first time period of exhausting the gas away from wafer support, and then the gas flows through the gas exhausts located in the peripheral portion and a gas exhaust located in the central portion of the manifold during a second time period.

20. The semiconductor device manufacturing tool of claim 19, wherein:
the flowrate of the gas flowing through the first openings ranges from 1 L/min to 20 L/min,
the flowrate of the gas flowing through the second openings located in the peripheral portion of the manifold ranges from 1 L/min to 20 L/min during the first time period and the second time period, and
the flowrate of the gas flowing through the second opening located in the central portion of the manifold ranges from 10 L/min to 80 L/min during the second time period.
